(19) United States
(12) Patent Application Publication
(10) Pub. No.: US 2018/0002561 A1
(43) Pub. Date: Jan. 4, 2018

(54) RESIN COMPOSITION FOR UNDERLAYER FILM FORMATION, IMPRINT FORMING KIT, LAMINATE, PATTERN FORMING METHOD, AND METHOD FOR PRODUCING DEVICE

(71) Applicant: FUJIFILM Corporation, Tokyo (JP)

(72) Inventors: Tadashi OOMATSU, Haibara-gun (JP); Hirotaka KITAGAWA, Haibara-gun (JP); Yuichiro GOTO, Haibara-gun (JP)

(73) Assignee: FUJIFILM Corporation, Tokyo (JP)

(21) Appl. No.: 15/702,065

(22) Filed: Sep. 12, 2017

Related U.S. Application Data
(63) Continuation of application No. PCT/JP2016/057903, filed on Mar. 14, 2016.

(30) Foreign Application Priority Data
Mar. 18, 2015 (JP) 2015-055375

(51) Int. Cl. C09D 133/14; B29C 59/02; C08F 8/00; G03F 7/00; C09D 7/12; B29K 105/00

(52) U.S. Cl. CPC C09D 133/14; G03F 7/0002; C09D 7/1233; B29C 59/022; C08F 8/00; B29K 2105/0014

(57) ABSTRACT

Disclosed herein are a resin composition for underlayer film formation which is capable of forming an underlayer film having good adhesiveness to a base material and good surface state, an imprint forming kit, a laminate, a pattern forming method, and a method for producing a device. Provided is a resin composition for underlayer film formation, including a resin, a nucleophilic catalyst, and a solvent, in which the content of the nucleophilic catalyst is 0.01 to 0.3 mass % with respect to the solid content of the resin composition for underlayer film formation.

### CROSS-REFERENCE TO RELATED APPLICATIONS

This application is a Continuation of PCT International Application No. PCT/JP2016/057903 filed on Mar. 14, 2016, which claims priority under 35 U.S.C. §119(a) to Japanese Patent Application No. 2015-055375 filed on Mar. 18, 2015. Each of the above application(s) is hereby expressly incorporated by reference, in its entirety, into the present application.

### BACKGROUND OF THE INVENTION

### 1. Field of the Invention

The present invention relates to a resin composition for underlayer film formation, an imprint forming kit, a laminate, a pattern forming method, and a method for producing a device.

### 2. Description of the Related Art

The imprinting technology is a development advanced from an embossing technique known in the art of optical disc production, which accurately transfers a fine pattern of a mold prototype having a concave-convex pattern formed on its surface (which is generally referred to as a “mold”, “stamper”, or “template”). In this technology, once the mold is fabricated, microstructures such as nanostructures can then be easily and repeatedly molded, which is therefore economical. Accordingly, in recent years, it has been anticipated that this technique will be applied to various technical fields.

Two methods of imprinting technology have been proposed; one is a thermal imprinting method using a thermoplastic resin as the material to be processed (for example, see S. Chou et al.: Appl. Phys. Lett. Vol. 67, 3114 (1995)), and the other is a photoimprinting method using a photocurable composition (for example, see M. Colbun et al.: Proc SPIE, Vol. 3676, 379 (1999)). In the thermal imprinting method, a mold is pressed against a thermoplastic resin heated up to a temperature equal to or higher than the glass transition temperature thereof, then the thermoplastic resin is cooled to a temperature equal to or lower than the glass transition temperature thereof, and thereafter the mold is peeled to thereby transfer the microstructure of the mold onto the resin.

On the other hand, photoimprinting is a method of transferring a fine pattern onto a photo-cured product, by allowing a photocurable composition to cure under photoirradiation through a light transmissive mold or a light transmissive substrate, and then peeling the mold. This method is applicable to the field of high-precision processing for forming ultrafine patterns such as fabrication of semiconductor integrated circuits, since the imprinting may be implemented at room temperature.

Along with the activation of the photoimprinting method, adhesiveness between the base material and the photocurable composition has become a problem. In photoimprinting, the photocurable composition is applied over the surface of the base material, the photocurable composition is allowed to cure under photoirradiation, in a state of the surface of the base material being in contact with a mold, and then the mold is peeled. In the step of peeling the mold, there may be a case where the cured product is peeled from the base material and unfortunately adheres to the mold. This is thought to be because the adhesiveness between the base material and the cured product is lower than the adhesiveness between the mold and the cured product. As a solution to the foregoing problem, a resin composition for underlayer film formation for improving the adhesiveness between the base material and the cured product has been studied (JP2009-503139A and JP2010-526426A).

### SUMMARY OF THE INVENTION

A resin composition for underlayer film formation is required to be capable of forming an underlayer film having good adhesiveness to a base material and a favorable surface state of the surface.

That is, if the surface state of the surface of the underlayer film formed on the base material is insufficient, in the case where a photocurable composition is applied onto the surface of the underlayer film, the photocurable composition hardly wet-spreads and the filling property of the photocurable composition to the pattern portion of the mold decreases, which may result in pattern defects or the like. Furthermore, sufficient adhesiveness between the photocurable composition layer and the underlayer film cannot be obtained in the region where the coating defects of the underlayer film exists, and in the case where the mold is released from the photocurable composition layer, there is a concern that a part of the photocurable composition layer is peeled off and adheres to the mold side.

In addition, if the adhesiveness of the underlayer film to the base material is insufficient, the photocurable composition layer may peel off and adhere to the mold side in the case where the mold is released from the photocurable composition layer.

The present inventors have examined the resin composition for underlayer film formation disclosed in JP2009-503139A and JP2010-526426A and found that the adhesiveness to a base material and the surface state of the surface of an underlayer film are insufficient.

Accordingly, it is an object of the present invention to provide a resin composition for underlayer film formation which is capable of forming an underlayer film having good adhesiveness to a base material and good surface state of the surface, an imprint forming kit, a laminate, a pattern forming method, and a method for producing a device.

As a result of extensive studies, the present inventors have found that it is possible to form an underlayer film having good adhesiveness to a base material and good surface state of the surface, by incorporating a nucleophilic catalyst in the resin composition for underlayer film formation in an amount of 0.01 to 3 mass % with respect to the solid content of the resin composition for underlayer film formation. The present invention has been completed based on such a finding. The present invention provides the following.

<1> A resin composition for underlayer film formation, comprising a resin, a nucleophilic catalyst, and a solvent, in which the content of the nucleophilic catalyst is 0.01 to 0.3 mass % with respect to the solid content of the resin composition for underlayer film formation.

<2> The resin composition for underlayer film formation according to <1>, in which the nucleophilic catalyst is at least one selected from an ammonium salt, a phosphine-based compound, a phosphonium salt, and a heterocyclic compound.

<3> The resin composition for underlayer film formation according to <1> or <2>, in which the resin includes a resin having a radical reactive group.

<4> The resin composition for underlayer film formation according to any one of <1> to <3>, in which the resin includes a resin having a radical reactive group and at least one group selected from a group represented by General Formula (B), an oxiranyl group, an oxetanyl group, a nonionic hydrophilic group, and a group having an interaction with a base material in the side chain thereof,

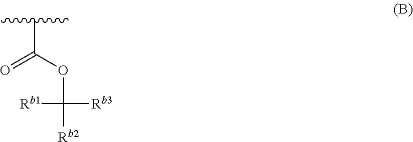

in General Formula (B), the wavy line represents a position connectings to the main chain or side chain of the resin, and

R^{b1}, R^{b2}, and R^{b3} each independently represent a group selected from an unsubstituted linear alkyl group having 1 to 20 carbon atoms, an unsubstituted branched alkyl group having 3 to 20 carbon atoms, and an unsubstituted cycloalkyl group having 3 to 20 carbon atoms, and

two of R^{b1}, R^{b2}, and R^{b3} may be bonded to each other to form a ring.

<5> The resin composition for underlayer film formation according to any one of <1> to <4>, in which the resin has at least one repeating unit selected from General Formulae (X1) to (X4),

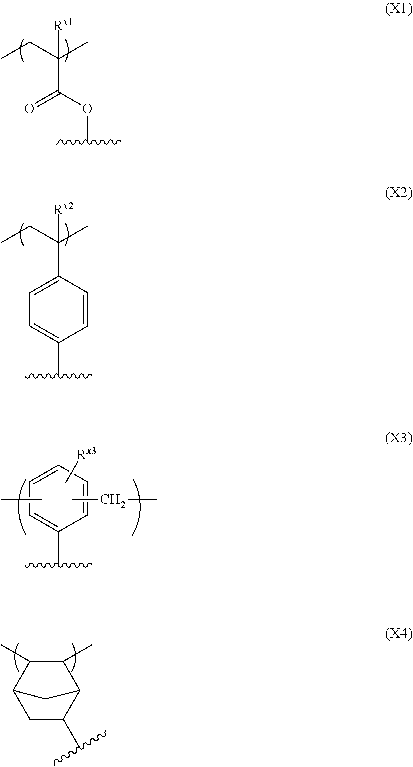

in General Formulae (X1) to (X4), R^{X1}, R^{X2}, and R^{X3} each independently represent a hydrogen atom or a methyl group, and the wavy line represents a position connecting to an atom or atomic group constituting a repeating unit of the resin.

<6> The resin composition for underlayer film formation according to any one of <1> to <5>, in which the content of water is 0.01 to 3 mass % with respect to the resin composition for underlayer film formation.

<7> The resin composition for underlayer film formation according to any one of <1> to <6>, in which the content of the solvent is 95 to 99.9 mass % with respect to the resin composition for underlayer film formation.

<8> The resin composition for underlayer film formation according to any one of <1> to <7>, which is used for the formation of an underlayer film for photoimprints.

<9> An imprint forming kit comprising the resin composition for underlayer film formation according to any one of <1> to <8> and a photocurable composition.

<10> A laminate comprising an underlayer film obtained by curing the resin composition for underlayer film formation according to any one of <1> to <8> on a surface of a base material.

<11> A pattern forming method, comprising:

applying the resin composition for underlayer film formation according to any one of <1> to <8> onto the surface of a base material in the form of layer;

heating the applied resin composition for underlayer film formation to form an underlayer film;

applying a photocurable composition in the form of layer onto the surface of the underlayer film, or a mold having a pattern;

sandwiching the photocurable composition between the mold and the base material;

curing the photocurable composition by photoirradiation in a state of the photocurable composition being sandwiched between the mold and the base material; and

peeling the mold.

<12> A method for producing a device comprising the pattern forming method according to <11>.

According to the present invention, it has become possible to provide a resin composition for underlayer film formation which is capable of forming an underlayer film having good adhesiveness to a base material and good surface state of the surface, an imprint forming kit, a laminate, a pattern forming method, and a method for producing a device.

### BRIEF DESCRIPTION OF THE DRAWINGS

FIG. 1 is a view showing an example of a production process in the case where a photocurable composition for imprints is used for processing of a base material by etching.

### DESCRIPTION OF THE PREFERRED EMBODIMENTS

The contents of the present invention will be described in detail hereinunder.

As used herein, the numerical value ranges shown with “to” means ranges including the numerical values indicated before and after “to” as the minimum and maximum values, respectively.

As used herein, the term “(meth)acrylate” refers to acrylate and methacrylate; “(meth)acrylic” refers to acrylic and methacrylic; and “(meth)acryloyl” refers to acryloyl and methacryloyl. The term “(meth)acryloyloxy” refers to acryloyloxy and methacryloyloxy.

As used herein, the term “imprint” is preferably meant to indicate pattern transfer in a size of 1 nm to 10 mm and more preferably meant to indicate pattern transfer in a size of about 10 nm to 100 um (nanoimprint).

Regarding the expression of “group (atomic group)” as used herein, the expression with no indication of “substituted” or “unsubstituted” includes both “substituted group” and “unsubstituted group”. For example, “alkyl group” includes not only an alkyl group not having a substituent (unsubstituted alkyl group) but also an alkyl group having a substituent (substituted alkyl group).

As used herein, the term “light” includes not only those in the wavelength regions of ultraviolet, near-ultraviolet, far ultraviolet, visible light and infrared, and other electromagnetic waves, but also radiation rays. The radiation rays include microwaves, electron beams, EUV and X-rays. Laser light such as 248 nm excimer laser, 193 nm excimer laser, and 172 nm excimer laser may also be used. These sorts of light may be monochromatic light (single wavelength light) which have passed through an optical filter, or light that includes a plurality of different wavelengths (complex light).

Unless otherwise specified, the weight-average molecular weight and the number-average molecular weight (Mn) in the present invention refer to those as measured by gel permeation chromatography (GPC).

As used herein, the term “solid content” refers to the total mass of component(s) remaining when a solvent is excluded from the entire composition.

As used herein, the term “solid content” is a solid content at 25° C.

<Resin Composition for Underlayer Film Formation>

The resin composition for underlayer film formation according to the present invention is a resin composition for underlayer film formation which contains a resin, a nucleophilic catalyst, and a solvent and is used for being applied onto a base material to form an underlayer film, in which the content of the nucleophilic catalyst in the solid content of the resin composition for underlayer film formation is 0.01 to 3 mass %.

By applying the resin composition for underlayer film formation according to the present invention onto a base material, it is possible to form an underlayer film having good adhesiveness to the base material and good surface state of the surface.

That is, the resin composition for underlayer film formation according to the present invention contains a nucleophilic catalyst in a solid content of the resin composition for underlayer film formation in an amount of 0.01 mass % or more, whereby the adhesiveness to a base material is improved. Although the mechanism by which the adhesiveness is improved is not certain, it is presumed to be due to the fact that the covalent bond formation reaction between the functional group on the surface of the base material and the resin for forming an underlayer film is catalytically promoted.

On the other hand, by setting the content of the nucleophilic catalyst to 3 mass % or less with respect to the solid content of the resin composition for underlayer film formation, it is possible to form an underlayer film with good surface state of the surface. It is considered to be due to the fact that precipitation of a nucleophilic catalyst and phase separation can be suppressed in the step of applying and drying the underlayer film resin composition.

The resin composition for underlayer film formation according to the present invention is capable of forming an underlayer film having good adhesiveness to a cured product of a photocurable composition and can therefore be preferably used for the formation of an underlayer film for photoimprints.

Each component of the resin composition for underlayer film formation according to the present invention will be described below.

<Nucleophilic Catalyst>

The resin composition for underlayer film formation according to the present invention contains at least one nucleophilic catalyst. The nucleophilic catalyst has a catalytic mechanism different from that of an acid catalyst, a Lewis acid catalyst, or a basic catalyst, and expresses a catalytic action by a nucleophilic reaction. Examples of the nucleophilic catalyst include an ammonium salt, a phosphine-based compound, a phosphonium salt, and a heterocyclic compound.

The ammonium salt may be, for example, a salt of an ammonium cation represented by General Formula (AM1) or (AM2) with an anion. The anion may be bonded to a part of any one of the ammonium cations through a covalent bond and may be present outside the molecule of the ammonium cation.

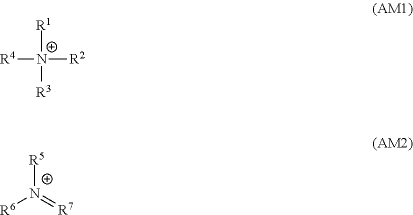

In General Formulae (AM1) and (AM2), R¹ to R⁷ each independently represent a hydrocarbon group which may be substituted. R¹ and R², R³ and R⁴, R⁵ and R⁶, and R⁵ and R⁷ may be independently bonded to each other to form a ring. R¹ to R⁷ are preferably unsubstituted hydrocarbon groups.

Specific examples of the ammonium salt include tetramethylammonium chloride, benzyltrimethylammonium chloride, trioctylmethylammonium chloride, tetraethylammonium bromide, tetrabutylammonium bromide, cetyltrimethylammonium bromide, benzyltriethylammonium bromide, tetraethylammonium iodide, and tetrabutylammonium iodide.

The phosphine-based compound may be, for example, a compound represented by General Formula (PP1).

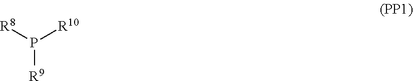

In General Formula (PP1), R⁸ to R¹⁰ each independently represent a hydrocarbon group which may be substituted. R⁸ and R⁹, and R⁹ and R¹⁰ may be respectively bonded to each other to form a ring.

Specific examples of the phosphine-based compound include tributylphosphine, tricyclohexylphosphine, triphenylphosphine, tri(o-tolyl)phosphine, and 1,3,5-triaza-7-phosphaadamantane.

Specific examples of the phosphonium salt include ethyltriphenylphosphonium chloride, tetrabutylphosphonium bromide, ethyltriphenylphosphonium bromide, tetrabutylphosphonium iodide, and ethyltriphenylphosphonium iodide.

Specific examples of the heterocyclic compound include pyridines such as pyridine and dimethylaminopyridine, imidazoles such as imidazole, 2-methylimidazole, 2-phenylimidazole, 2-undecylimidazole, 1-benzyl-2-methylimidazole, and cyanoethyl-2-methylimidazole, triazoles, imidazoliums such as 1,3-dimesityl imidazolium chloride, 1-butyl-3-methylimidazolium iodide, and 1,3-bis(2,6-diisopropylphenyl)imidazolium chloride, triazoliums such as 1,4-dimethyl-1,2,4-triazolium iodide and 6,7-dihydro-2-mesityl-5H-pyrrolo[2,1-c]-1,2,4-triazolium perchlorate, and thiazoliums such as 3-benzyl-5-(2-hydroxyethyl)-4-methylthiazolium chloride and 3-ethyl-5-(2-hydroxyethyl)-4-methylthiazolium bromide.

In the resin composition for underlayer film formation according to the present invention, the nucleophilic catalyst is preferably an ammonium salt, a phosphine-based compound, a phosphonium salt, and a heterocyclic compound, and more preferably a phosphine-based compound, a phosphonium salt, and a heterocyclic compound, among which triphenylphosphine, imidazoles, and pyridines are particularly preferable.

The resin composition for underlayer film formation according to the present invention contains a nucleophilic catalyst in an amount of 0.01 to 3 mass % with respect to the solid content of the resin composition for underlayer film formation. The upper limit of the content of the nucleophilic catalyst is preferably 2 mass % or less, more preferably 1 mass % or less, and still more preferably 0.5 mass % or less. The lower limit of the content of the nucleophilic catalyst is preferably 0.02 mass % or more, more preferably 0.03 mass % or more, and still more preferably 0.05 mass % or more. In the case where the content of the nucleophilic catalyst is 0.01 mass % or more, it is possible to form an underlayer film having good adhesiveness to the base material. Further, in the case where the content of the nucleophilic catalyst is 3 mass % or less, it is possible to form an underlayer film having good surface state.

<Resin>

The resin composition for underlayer film formation according to the present invention contains a resin. The resin is preferably a resin having a radical reactive group, and more preferably a resin having a radical reactive group in the side chain thereof. By using a resin having a radical reactive group, it is possible to form an underlayer film having good adhesiveness to the cured product layer of the photocurable composition (hereinafter, also referred to as an imprint layer).

Examples of the radical reactive group include a (meth)acryloyl group, a (meth)acryloyloxy group, a maleimide group, an allyl group, and a vinyl group, among which a (meth)acryloyl group, a (meth)acryloyloxy group, an allyl group, and a vinyl group are preferable, a (meth)acryloyl group and a (meth)acryloyloxy group are more preferable, and a (meth)acryloyloxy group is particularly preferable. According to this aspect, it is possible to further improve the adhesiveness of the obtained underlayer film to the imprint layer.

The resin preferably has at least one repeating unit selected from General Formulae (X1) to (X4), more preferably has at least one repeating unit selected from General Formulae (X1) to (X3), and still more preferably has a repeating unit represented by General Formula (X1). According to this aspect, the obtained underlayer film has an excellent affinity with the base material and tends to be excellent in coatability of a thin film of several nm to several tens of nm.

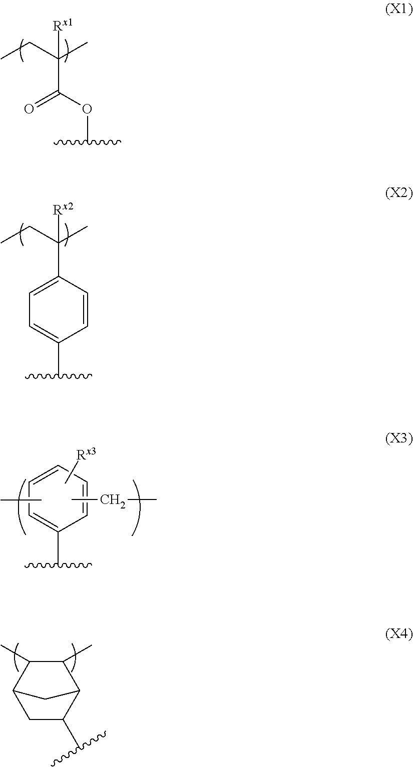

In General Formulae (X1) to (X4), R^{X1}, R^{X2}, and R^{X3} each independently represent a hydrogen atom or a methyl group, and the wavy line represents a position connecting to an atom or atomic group constituting a repeating unit of the resin.

In the present invention, the resin preferably has a radical reactive group, and at least one group selected from a group represented by General Formula (B), an oxiranyl group, an oxetanyl group, a nonionic hydrophilic group, and a group having an interaction with a base material in the side chain thereof. Hereinafter, an oxiranyl group and an oxetanyl group are collectively referred to as a cyclic ether group.

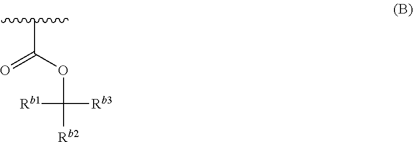

In General Formula (B), the wavy line represents a position connecting to the main chain or side chain of the resin,

R^{b1}, R^{b2}, and R^{b3} each independently represent a group selected from an unsubstituted linear alkyl group having 1 to 20 carbon atoms, an unsubstituted branched alkyl group having 3 to 20 carbon atoms, and an unsubstituted cycloalkyl group having 3 to 20 carbon atoms, and

Two of R^{b1}, R^{b2}, and R^{b3} may be bonded to each other to form a ring.

In the present invention, a preferred aspect of the resin is a resin having a radical reactive group and a group represented by General Formula (B) in the side chain thereof (first aspect), a resin having a radical reactive group and a cyclic ether group in the side chain thereof (second aspect), a resin having a radical reactive group and a nonionic hydrophilic group in the side chain thereof (third aspect), and a resin having a radical reactive group and a group having an interaction with a base material in the side chain thereof (fourth aspect).

As for the resin, the resin of each of the above aspects may be used alone, or the resins of each aspect may be used in combination. In addition, the resin of each aspect may be used alone or in combination of two or more thereof. Examples of commercially available resins include NK OLIGO EA 7120, EA 7140, EA 7420, and EA 7440 (manufactured by Shin-Nakamura Chemical Co., Ltd.).

The resin of each aspect will be described below.

<<Resin of First Aspect>>

The resin of the first aspect is a resin having a radical reactive group and a group represented by General Formula (B) in the side chain thereof. The group represented by General Formula (B) is more readily susceptible to the deprotection reaction of a tertiary ester by at least one of an acid or heating, due to carbocation intermediates in the deprotection reaction, or low energy of the transition state of the reaction. Therefore, it is easy to form an underlayer film having a high adhesive force to an imprint layer and a base material.

The resin of the first aspect preferably has a group represented by General Formula (A) and a group represented by General Formula (B) in the side chain thereof.

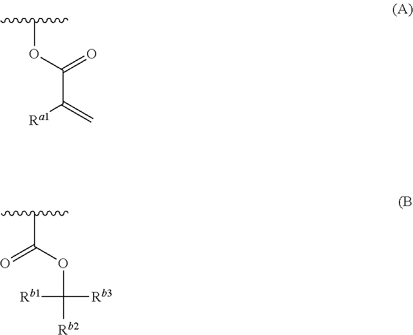

In General Formulae (A) and (B), the wavy line represents a position connecting to the main chain or side chain of the resin,

R^{al} represents a hydrogen atom or a methyl group, and

R^{b1}, R^{b2}, and R^{b3} each independently represent a group selected from an unsubstituted linear alkyl group having 1 to 20 carbon atoms, an unsubstituted branched alkyl group having 3 to 20 carbon atoms, and an unsubstituted cycloalkyl group having 3 to 20 carbon atoms, and two of R^{b1}, R^{b2}, and R^{b3} may be bonded to each other to form a ring.

R^{b1}, R^{b2}, and R^{b3} each independently represent a group selected from an unsubstituted linear alkyl group having 1 to 20 carbon atoms, an unsubstituted branched alkyl group having 3 to 20 carbon atoms, and an unsubstituted cycloalkyl group having 3 to 20 carbon atoms.

The number of carbon atoms in the unsubstituted linear alkyl group is 1 to 20, preferably 1 to 15, and more preferably 1 to 10. Specific examples of the unsubstituted linear alkyl group include a methyl group, an ethyl group, a propyl group, a hexyl group, and an octyl group.

The number of carbon atoms in the unsubstituted branched alkyl group is 3 to 20, preferably 3 to 15, and more preferably 3 to 10. Specific examples of the unsubstituted branched alkyl group include an iso-propyl group, a sec-butyl group, a tert-butyl group, and an iso-butyl group.

The number of carbon atoms in the unsubstituted cycloalkyl group is 3 to 20, preferably 3 to 15, and more preferably 3 to 10. The cycloalkyl group may be monocyclic or polycyclic. Specific examples of the unsubstituted cycloalkyl group include a cyclopropyl group, a cyclobutyl group, a cyclopentyl group, a cyclohexyl group, a norbornyl group, an isobornyl group, a camphanyl group, an adamantyl group, a dicyclopentyl group, an α-pinenyl group, and a tricyclodecanyl group.

Two of R^{b1}, R^{b2}, and R^{b3} may be bonded to each other to form a ring. Examples of the ring formed by bonding two of R^{b1}, R^{b2}, and R^{b3} to each other include a cyclopentane ring, a cyclohexane ring, a norbornane ring, an isobornane ring, and an adamantane ring.

Further, it is not preferable to form a ring by bonding R^{b1}, R^{b2}, and R^{b3} to one another. This is because the deprotection reaction of a tertiary ester by at least one of an acid or heating hardly proceeds since carbocations at the bridgehead position are not stable. Examples of the group not preferable as —C(R^{b1})(R^{b2})(R^{b3}) include a 1-adamantyl group, a norborn-1-yl group, and an isoborn-1-yl group.

At least one of R^{b1}, R^{b1}, or R^{b3} is preferably a cycloalkyl group having 3 to 20 carbon atoms.

According to the above aspect, since the carbocation is likely to exist more stably, the deprotection reaction of a tertiary ester is more likely to proceed by at least one of an acid or heating.

The resin of the first aspect preferably has at least one repeating unit selected from General Formulae (II) to (IV).

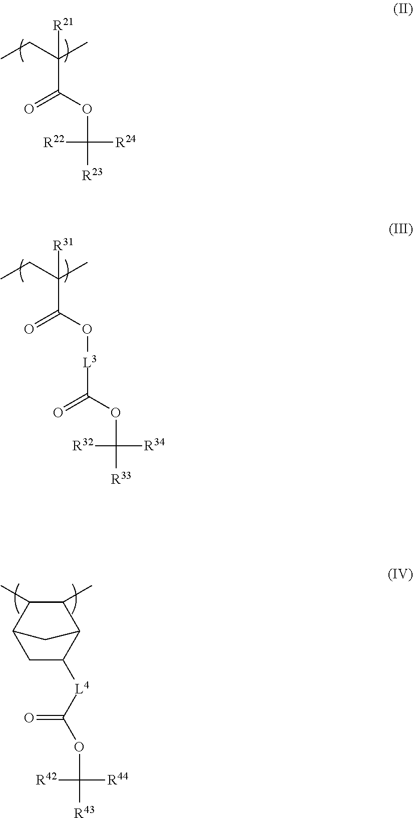

In General Formulae (II) to (IV), R²¹ and R³¹ each independently represent a hydrogen atom or a methyl group,

R²² to R²⁴, R³² to R³⁴, and R⁴² to R⁴⁴ each independently represent a group selected from an unsubstituted linear alkyl group having 1 to 20 carbon atoms, an unsubstituted branched alkyl group having 3 to 20 carbon atoms, and an unsubstituted cycloalkyl group having 3 to 20 carbon atoms, and R²³ and R²⁴, R³³ and R³⁴, and R⁴³ and R⁴⁴ may be bonded to each other to form a ring, and

L³ and L⁴ each independently represent a divalent linking group.

R²² to R²⁴, R³² to R³⁴, and R⁴² to R⁴⁴ have the same definition as in R^{b1} to R^{b3} of General Formula (B), and preferred ranges thereof are also the same.

L³ and L⁴ each independently represent a divalent linking group.

Examples of the divalent linking group include a linear or branched alkylene group, a cycloalkylene group, and a group formed by combining these groups. These groups may contain at least one selected from an ester bond, an ether bond, an amide bond, and a urethane bond. Additionally, these groups may be unsubstituted or may have a substituent. The substituent may be a hydroxyl group or the like.

The number of carbon atoms in the linear alkylene group is preferably 2 to 10.

The number of carbon atoms in the branched alkylene group is preferably 3 to 10.

The number of carbon atoms in the cycloalkylene group is preferably 3 to 10.

Specific examples of the divalent linking group include an ethylene group, a propylene group, a butylene group, a hexylene group, a 2-hydroxy-1,3-propanediyl group, a 3-oxa-1,5-pentanediyl group, and a 3,5-dioxa-1,8-octanediyl group.

The resin of the first aspect more preferably has a repeating unit represented by General Formula (I) and at least one of a repeating unit represented by General Formula (II) or a repeating unit represented by General Formula (III).

By including a repeating unit represented by General Formula (I), the resin can improve adhesiveness to an imprint layer. By including at least one of a repeating unit represented by General Formula (II) or a repeating unit represented by General Formula (III), it is possible to improve adhesiveness to a base material. Further, by using a resin containing the above-mentioned repeating units, it is possible to cure an underlayer film without using a low molecular weight crosslinking agent or the like, and it is possible to avoid occurrence of defects due to the sublimation of a crosslinking agent at the time of curing.

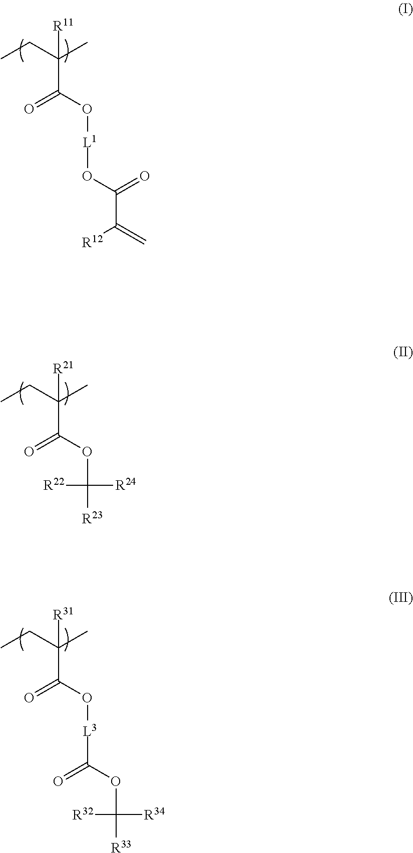

In General Formulae (I) to (III), R¹¹, R¹², R²¹, and R³¹ each independently represent a hydrogen atom or a methyl group,

R²² to R²⁴, and R³² to R³⁴ each independently represent a group selected from an unsubstituted linear alkyl group having 1 to 20 carbon atoms, an unsubstituted branched alkyl group having 3 to 20 carbon atoms, and an unsubstituted cycloalkyl group having 3 to 20 carbon atoms, and R²³ and R²⁴, and R³³ and R³⁴ may be respectively bonded to each other to form a ring, and

L¹ and L³ each independently represent a divalent linking group.

R²² to R²⁴, and R³² to R³⁴ have the same definition as in R^{b1} to R^{b3} of General Formula (B), and preferred ranges thereof are also the same.

R²⁴ and R³⁴ have the same definition as in R^{b3} of General Formula (B), and preferred ranges thereof are also the same.

L¹ and L³ each independently represent a divalent linking group.

The divalent linking group has the same definition as in the above-mentioned divalent linking group, and a preferred range thereof is also the same.

The resin of the first aspect preferably contains a repeating unit selected from a repeating unit where, in General Formula (II), at least one of R²², R²³, or R²⁴ is a cycloalkyl group having 3 to 20 carbon atoms, or R²³ and R²⁴ are bonded to each other to form a ring, and a repeating unit where, in General Formula (III), at least one of R³², R³³, or R³⁴ is a cycloalkyl group having 3 to 20 carbon atoms, or R³³ and R³⁴ are bonded to each other to form a ring. According to this aspect, the deprotection reaction of a tertiary ester is more likely to proceed by at least one of an acid or heating, since carbocations are likely to exist more stably.

The molar ratio of repeating units represented by General Formula (I): a total of repeating units represented by General Formula (II) and repeating units represented by General Formula (III) in the resin of the first aspect is preferably 5:95 to 95:5, more preferably 10:90 to 90:10, still more preferably 20:80 to 80:20, further preferably 30:70 to 70:30, and even more preferably 40:60 to 60:40.

When the ratio of General Formula (I) is set to 5 mol % or more, adhesiveness to an imprint layer can be improved, which is preferable. When the ratio of the repeating unit selected from General Formula (II) and General Formula (III) is set to 5 mol % or more, adhesiveness to a base material can be improved, which is preferable.

The resin of the first aspect may contain the other repeating unit other than repeating units represented by General Formulae (I) to (III). Examples of the other repeating unit include a repeating unit represented by General Formula (IV). Further examples of the other repeating unit include a repeating unit described in paragraphs “0022” to “0055” of JP2014-24322A, and a repeating unit represented by General Formula (V) and a repeating unit represented by General Formula (VI) described in paragraph “0043” of the same JP2014-24322A.

The content of the other repeating unit is preferably 10 mol % or less, more preferably 5 mol % or less, and still more preferably 1 mol % or less, with respect to the total content of repeating units in the resin. Further, it is also possible that the other repeating unit is not contained. In the case where the resin is composed only of repeating units represented by General Formulae (I) to (III), the above-mentioned effects of the present invention are more significantly obtained.

Specific examples of the repeating unit represented by General Formula (I) include the following structures. It is needless to say that the present invention is not limited thereto. R¹¹ and R¹² each independently represent a hydrogen atom or a methyl group, preferably a methyl group.

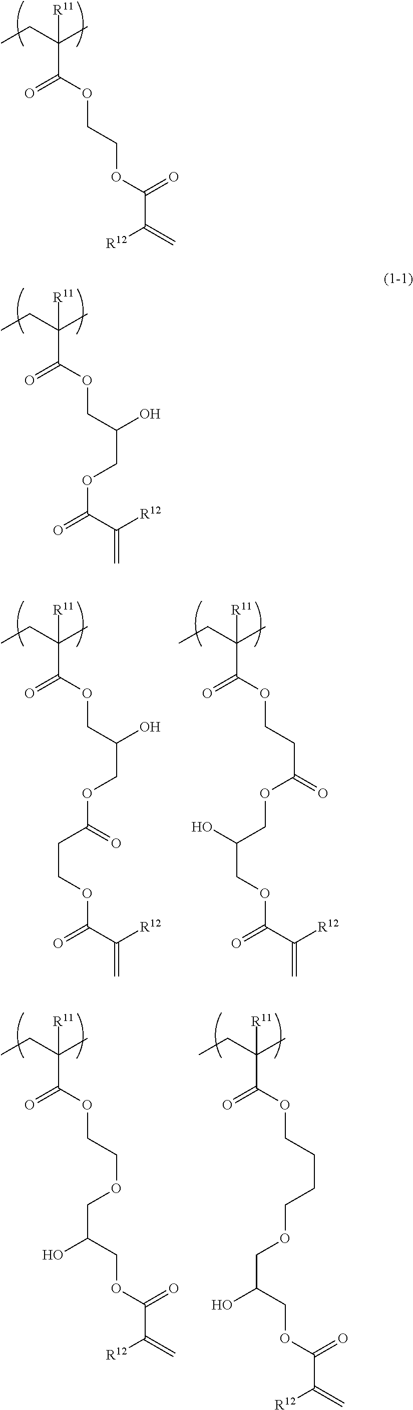

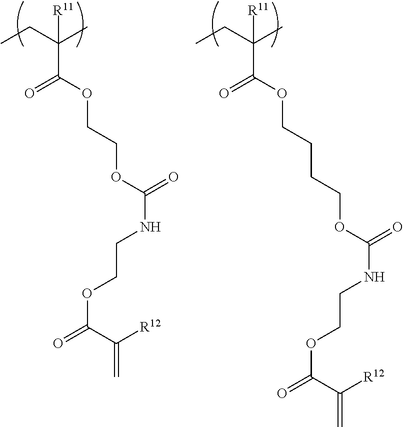

Specific examples of the repeating unit represented by General Formula (II) include the following structures.

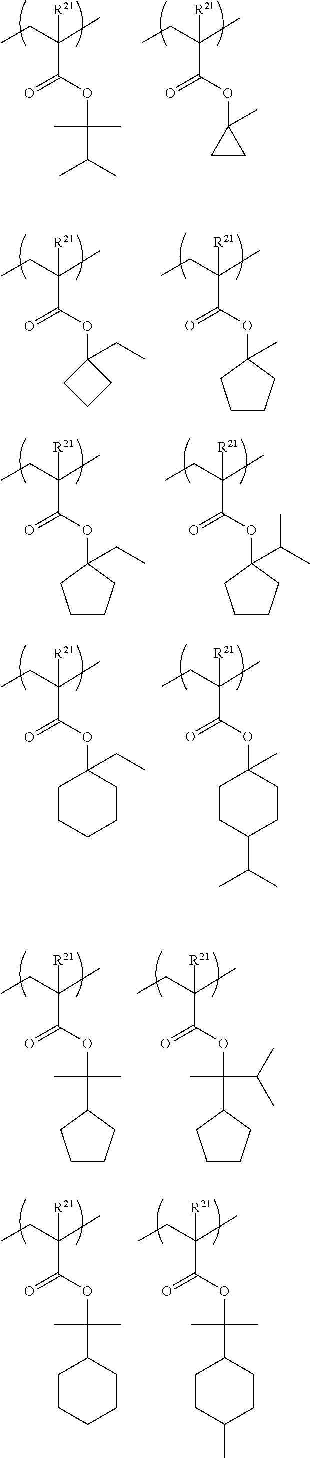

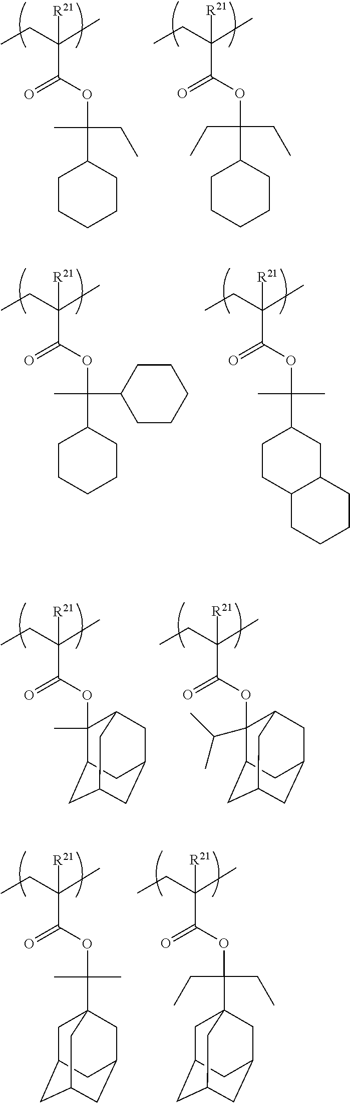

Specific examples of the repeating unit represented by General Formula (III) include the following structures.

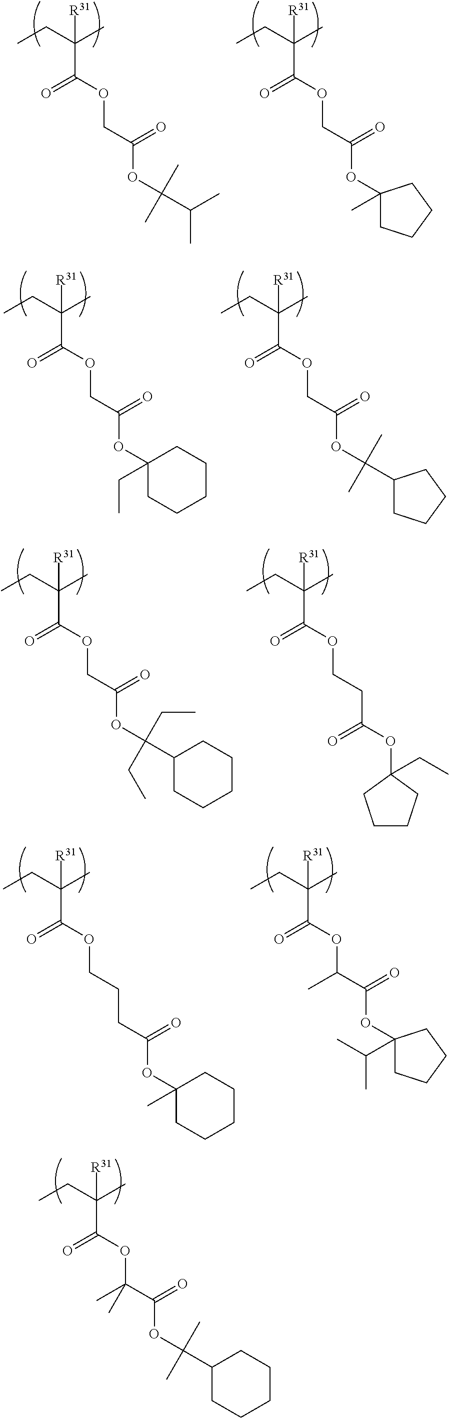

Specific examples of the repeating unit represented by General Formula (IV) include the following structures.

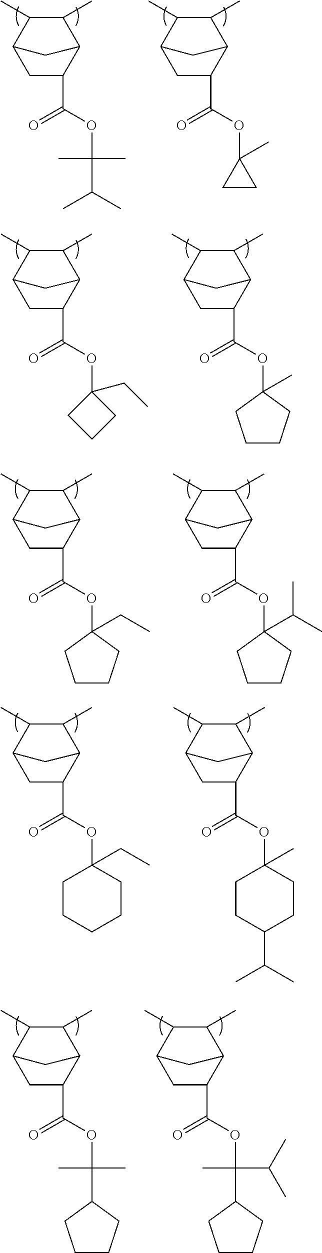

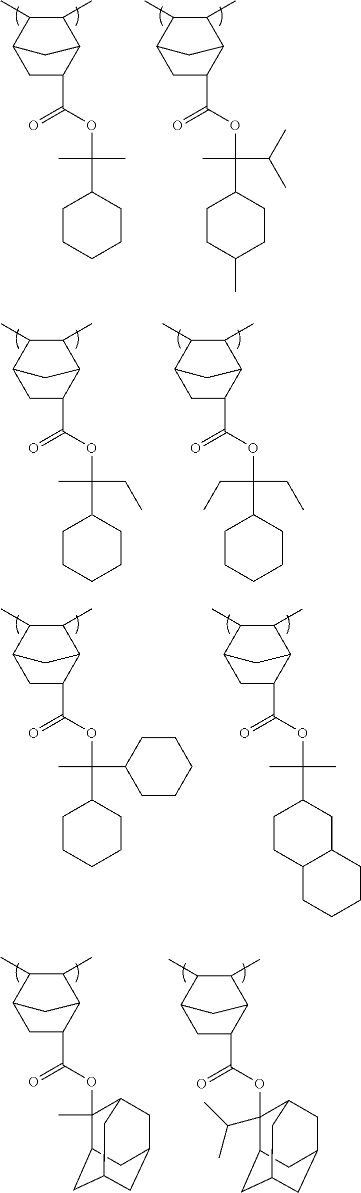

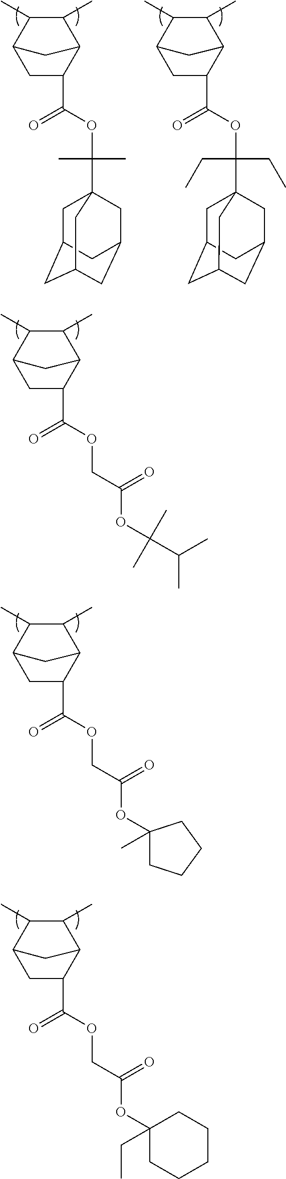

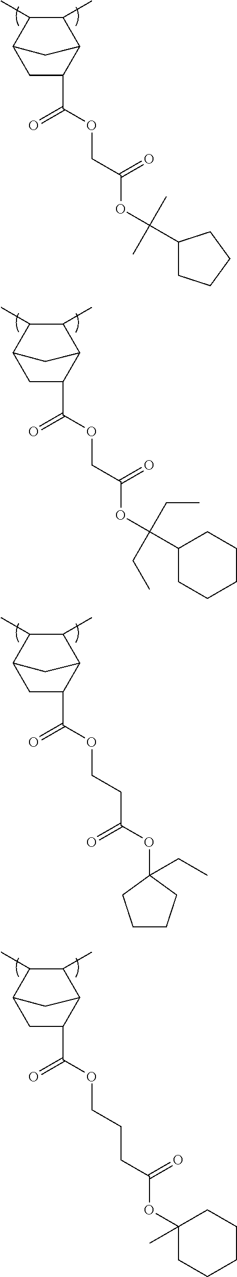

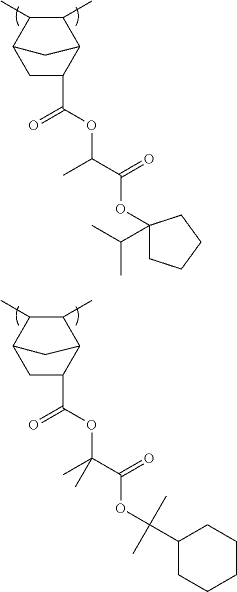

Hereinafter, specific examples of the resin of the first aspect are shown. In the following specific examples, x represents 5 to 99 mol %, and y represents 5 to 95 mol %.

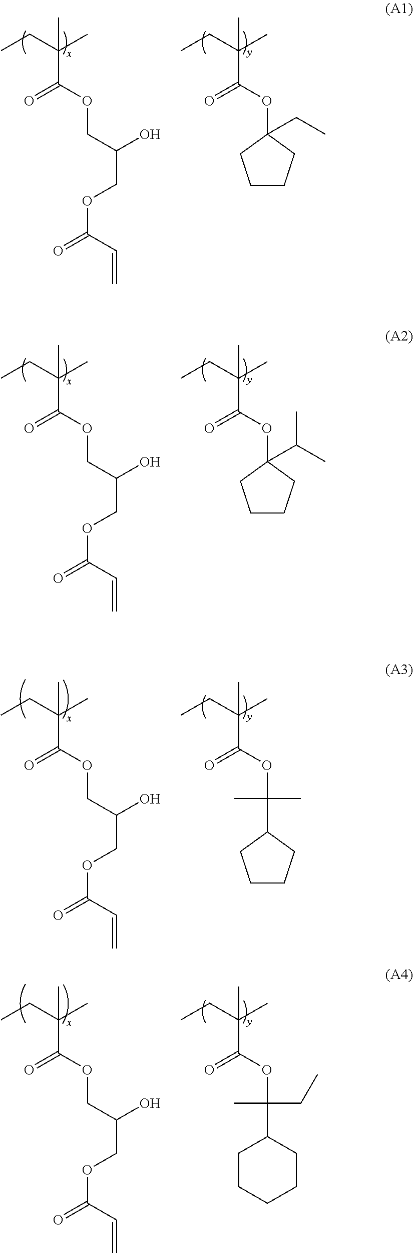

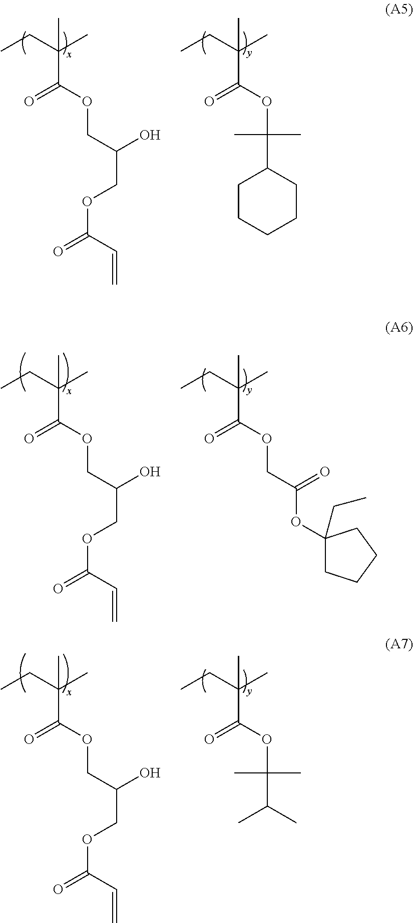

<<Resin of Second Aspect>>

The resin of the second aspect is a resin having a radical reactive group and a cyclic ether group in the side chain thereof. In the case where the resin has a group (cyclic ether group) selected from an oxiranyl group and an oxetanyl group, shrinkage upon thermal curing is suppressed and cracking or the like of the underlayer film surface is suppressed, whereby the surface state of the underlayer film can be improved.

The resin of the second aspect preferably has a repeating unit having a radical reactive group in the side chain thereof and a repeating unit having a cyclic ether group in the side chain thereof.

The molar ratio of repeating unit having a radical reactive group in the side chain thereof: repeating unit having a cyclic ether group in the resin of the second aspect is the repeating unit having a radical reactive group in the side chain thereof: repeating unit having a cyclic ether group of preferably 10:90 to 97:3, more preferably 30:70 to 95:5, and still more preferably 50:50 to 90:10. If the molar ratio is within the above-specified range, it is highly significant in that a better underlayer film can be formed even when curing at a low temperature.

The resin of the second aspect may contain repeating units other than the repeating unit having a radical reactive group in the side chain thereof and the cyclic ether group (hereinafter, often referred to as “other repeating units”). In the case of containing other repeating units, the ratio thereof is preferably 1 to 30 mol % and more preferably 5 to 25 mol %.

In the resin of the second aspect, the repeating unit having a radical reactive group in the side chain thereof is preferably at least one selected from the repeating units represented by General Formulae (1) to (3).

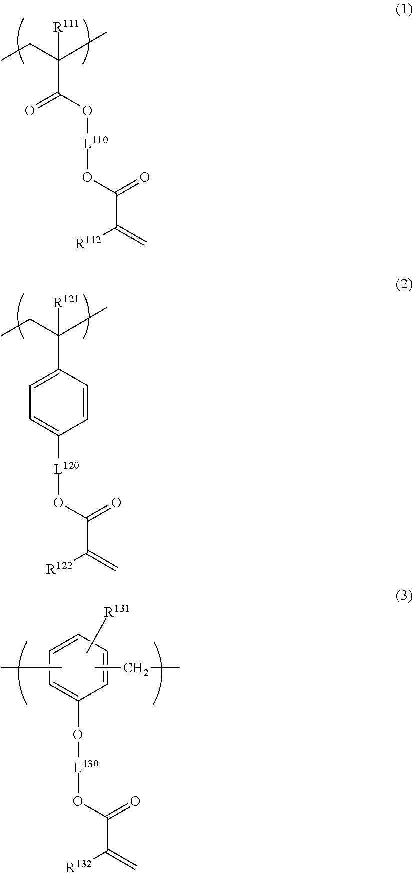

In General Formulae (1) to (3), R¹¹¹, R¹¹², R¹²¹, R¹²², R¹³¹, and R¹³² each independently represent a hydrogen atom or a methyl group, and L¹¹⁰, L¹²⁰, and L¹³⁰ each independently represent a single bond or a divalent linking group.

R¹¹¹ and R¹³¹ are preferably a methyl group. R¹¹², R¹²¹, R¹²², and R¹³² are preferably a hydrogen atom.

L¹¹⁰, L¹²⁰, and L¹³⁰ each independently represent a single bond or a divalent linking group. Examples of the divalent linking group include those described for L³ and L⁴ of General Formulae (III) and (IV), and a preferred range thereof is also the same. Among them, preferred is a group consisting of one or more —CH₂—, or a group consisting of a combination of one or more —CH₂— and at least one of —CH(OH)—, —O—, or —C(═O)—. The number of atoms constituting the linking chain of L¹¹⁰, L¹²⁰, and L¹³⁰ (for example, in General Formula (2), it refers to the number of atoms in the chain connecting a benzene ring to an oxygen atom adjacent to L¹²⁰) is preferably 1 to 20, and more preferably 2 to 10.

Specific examples of the repeating unit having a radical reactive group in the side chain thereof in the resin of the second aspect include the following structures. It is needless to say that the present invention is not limited thereto. R¹¹¹, R¹¹², R¹²¹, R¹²², R¹³¹, and R¹³² each independently represent a hydrogen atom or a methyl group.

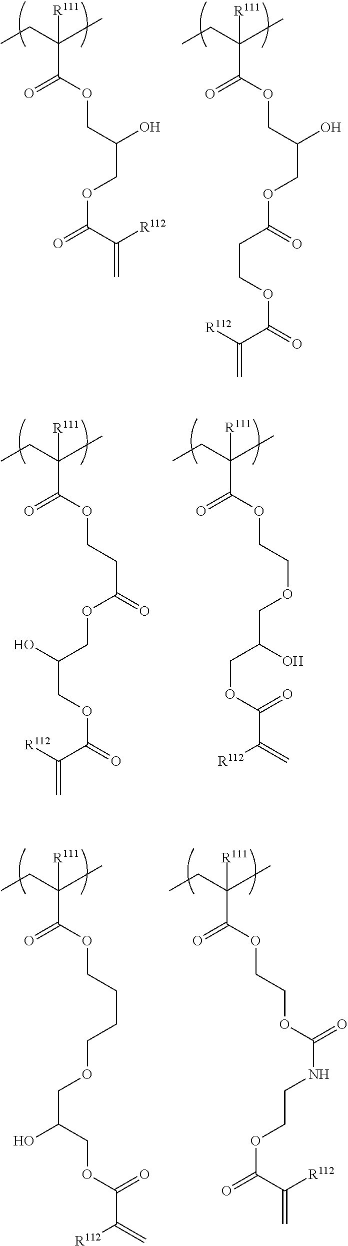

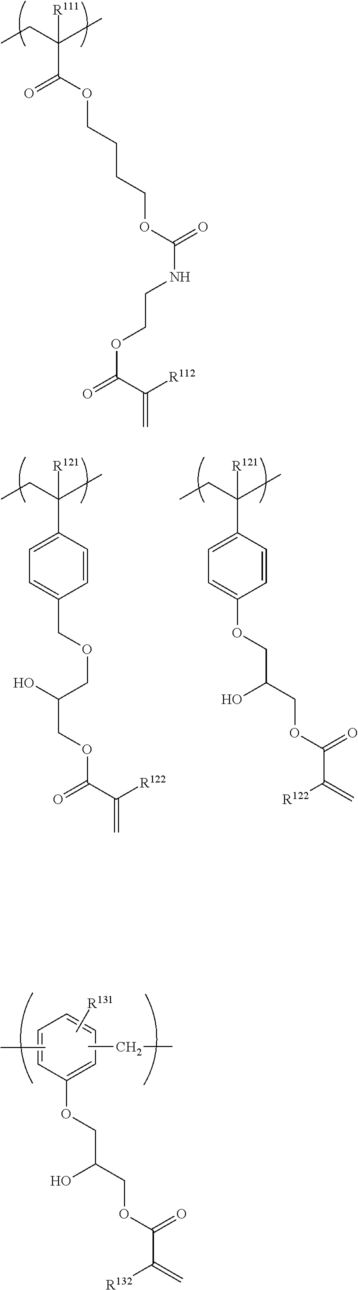

The repeating unit having a cyclic ether group is preferably at least one selected from the repeating units represented by General Formulae (4) to (6).

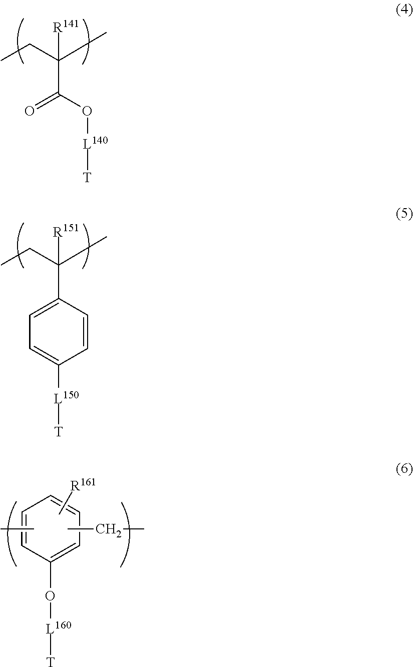

In General Formulae (4) to (6), R¹⁴¹, R¹⁵¹, and R¹⁶¹ each independently represent a hydrogen atom or a methyl group, L¹⁴⁰, L¹⁵⁰, and L¹⁶⁰ each independently represent a single bond or a divalent linking group, and T represents any one of cyclic ether groups represented by General Formulae (T-1), (T-2), and (T-3).

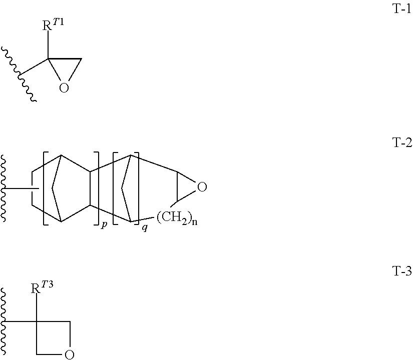

In General Formulae (T-1) to (T-3), R^{T1} and R^{T3} each independently represent a hydrogen atom or an alkyl group having 1 to 5 carbon atoms, p represents 0 or 1, q represents 0 or 1, n represents an integer of 0 to 2, and the wavy line represents a position connecting to L¹⁴⁰, L¹⁵⁰, or L¹⁶⁰.

R¹⁴¹ and R¹⁶¹ are preferably a methyl group, and R¹⁵¹ is preferably a hydrogen atom.

L¹⁴⁰, L¹⁵⁰, or L¹⁶⁰ each independently represents a single bond or a divalent linking group. Examples of the divalent linking group include those described for L³ and L⁴ of General Formulae (III) and (IV). Among them, preferred is a group consisting of one or more —CH₂—, or a group consisting of a combination of one or more —CH₂— and at least one of —CH(OH)—, —O—, or —C(═O)—, more preferred is a single bond or a group consisting of one or more —CH₂—, and still more preferred is a group consisting of 1 to 3 —CH₂—. The number of atoms constituting the linking chain of L¹⁴⁰, L¹⁵⁰, and L¹⁶⁰ is preferably 1 to 5, more preferably 1 to 3, and still more preferably 1 or 2.

R^{T1} and R^{T3} each independently represent a hydrogen atom or an alkyl group having 1 to 5 carbon atoms, and are preferably a hydrogen atom, a methyl group, an ethyl group or a propyl group and more preferably a hydrogen atom, a methyl group or an ethyl group.

p represents 0 or 1 and is preferably 0.

q represents 0 or 1 and is preferably 0.

n represents an integer of 0 to 2 and is preferably 0.

As for T, the groups represented by General Formulae (T-1) to (T-3) are preferably General Formula (T-1) and General Formula (T-2), and more preferably General Formula (T-1).

Examples of the repeating unit having a cyclic ether group include the following structures. It is needless to say that the present invention is not limited thereto. R¹⁴¹, R¹⁵¹, and R¹⁶¹ each independently represent a hydrogen atom or a methyl group.

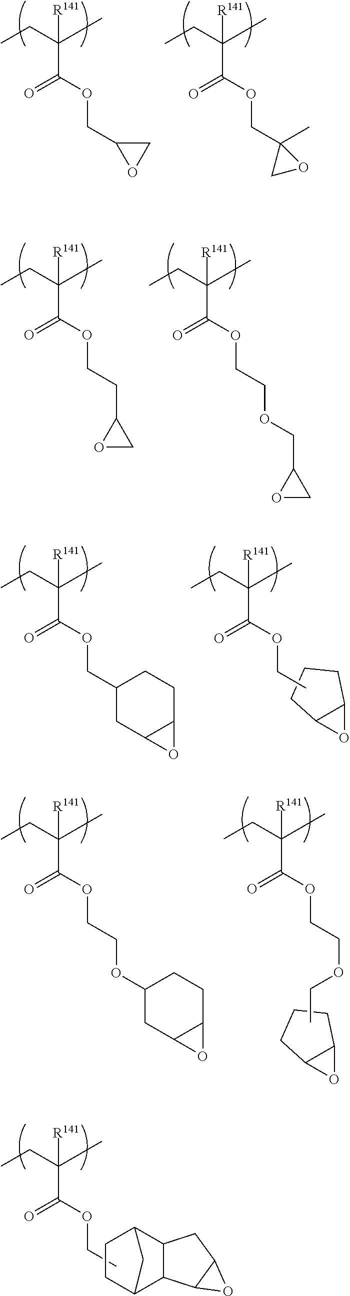

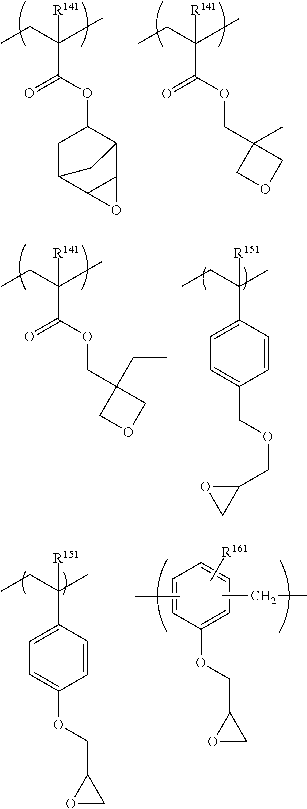

Other repeating units that may be contained in the resin of the second aspect are preferably a repeating unit represented by at least one of General Formula (7) or (8).

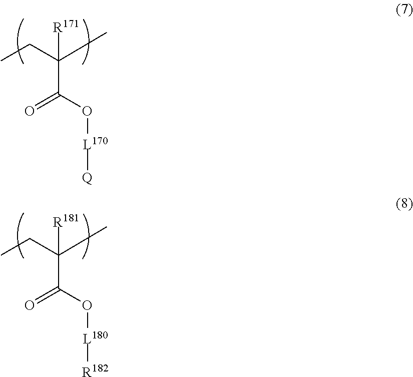

In General Formulae (7) and (8), R¹⁷¹ and R¹⁸¹ each independently represent a hydrogen atom or a methyl group, L¹⁷⁰ and L¹⁸⁰ each represent a single bond or a divalent linking group, Q represents a nonionic hydrophilic group, and R¹⁸² represents an aliphatic group having 1 to 12 carbon atoms, an alicyclic hydrocarbon group having 3 to 12 carbon atoms, or an aromatic group having 6 to 12 carbon atoms.

R¹⁷¹ and R¹⁸¹ each represent a hydrogen atom or a methyl group, and are more preferably a methyl group.

L¹⁷⁰ and L¹⁸⁰ each represent a single bond or a divalent linking group. Examples of the divalent linking group include those described for L³ and L⁴ of General Formulae (III) and (IV). The number of atoms constituting the linking chain of L¹⁷⁰ and L¹⁸⁰ is preferably 1 to 10.

Q represents a nonionic hydrophilic group. Examples of the nonionic hydrophilic group include an alcoholic hydroxyl group, a phenolic hydroxyl group, an ether group (preferably a polyoxyalkylene group), an amido group, an imido group, a ureido group, a urethane group, and a cyano group. Among them, an alcoholic hydroxyl group, a polyoxyalkylene group, a ureido group, and a urethane group are preferable and an alcoholic hydroxyl group and a urethane group are particularly preferable.

R¹⁸² represents an aliphatic group having 1 to 12 carbon atoms, an alicyclic group having 3 to 12 carbon atoms, or an aromatic group having 6 to 12 carbon atoms.

Examples of the aliphatic group having 1 to 12 carbon atoms include alkyl groups having 1 to 12 carbon atoms (for example, a methyl group, an ethyl group, a propyl group, an isopropyl group, a butyl group, an isobutyl group, a t-butyl group, a pentyl group, an isopentyl group, a neopentyl group, a hexyl group, a heptyl group, an octyl group, a 2-ethylhexyl group, a 3,3,5-trimethylhexyl group, an isooctyl group, a nonyl group, an isononyl group, a decyl group, an isodecyl group, an undecyl group, and a dodecyl group).

Examples of the alicyclic group having 3 to 12 carbon atoms include cycloalkyl groups having 3 to 12 carbon atoms (for example, a cyclopentyl group, a cyclohexyl group, a norbornyl group, an isobornyl group, an adamantyl group, and a tricyclodecanyl group).

Examples of the aromatic group having 6 to 12 carbon atoms include a phenyl group, a naphthyl group, and a biphenyl group. Among them, preferred are a phenyl group and a naphthyl group.

The aliphatic group, the alicyclic group, and the aromatic group may have a substituent, but preferably have no substituent.

The resin of the second aspect is preferably a resin containing a repeating unit represented by General Formula (1) and a repeating unit represented by General Formula (4), a resin containing a repeating unit represented by General Formula (2) and a repeating unit represented by General Formula (5), or a resin containing a repeating unit represented by General Formula (3) and a repeating unit represented by General Formula (6), and more preferably a resin containing a repeating unit represented by General Formula (1a) and a repeating unit represented by General Formula (4a), a resin containing a repeating unit represented by General Formula (2a) and a repeating unit represented by General Formula (5a), or a resin containing a repeating unit represented by General Formula (3a) and a repeating unit represented by General Formula (6a).

Specific examples of the resin of the second aspect include the resins described in paragraphs “0040” to “0042” of JP2014-192178A, the contents of which are incorporated herein by reference in its entirety.

<<Resin of Third Aspect>>

The resin of the third aspect is a resin having a radical reactive group and a nonionic hydrophilic group in the side chain thereof.

The nonionic hydrophilic group in the present invention refers to a nonionic polar group containing one or more heteroatoms (preferably N or O).

Examples of the nonionic hydrophilic group include an alcoholic hydroxyl group, a phenolic hydroxyl group, an ether group (preferably a polyoxyalkylene group or a cyclic ether group), an amino group (including a cyclic amino group), an amide group, an imide group, a ureido group, a urethane group, a cyano group, a sulfonamide group, a lactone group, and a cyclocarbonate group. Among them, an alcoholic hydroxyl group, a polyoxyalkylene group, an amino group, an amide group, a ureido group, a urethane group, and a cyano group are preferable, an alcoholic hydroxyl group, a urethane group, a polyoxyalkylene group, and a ureido group are more preferable, and an alcoholic hydroxyl group and a urethane group are particularly preferable.

In the resin of the third aspect, the content of the repeating unit containing a radical reactive group is preferably 20 mol % or more, more preferably 30 mol % or more, still more preferably 40 mol % or more, and particularly preferably 50 mol % or more.

In the resin of the third aspect, the content of the repeating unit containing a nonionic hydrophilic group is preferably 40 mol % or more, more preferably 50 mol % or more, still more preferably 60 mol % or more, and particularly preferably 70 mol %.

The radical reactive group and the nonionic hydrophilic group may be contained in the same repeating unit or may be contained in separate repeating units.

Furthermore, the resin of the third aspect may contain the other repeating unit not containing both an ethylenically unsaturated group and a nonionic hydrophilic group. The ratio of the other repeating unit in the resin is preferably 50 mol % or less.

The resin of the third aspect has an acid value of preferably less than 1.0 mmol/g, more preferably less than 0.3 mmol/g, and still more preferably less than 0.05 mmol/g. It is particularly preferred that the resin of the third aspect is substantially free of an acid group. Here, the phrase “substantially free of an acid group” means that the amount of an acid group is below the detection limit when it is measured, for example, by the following method. In addition, the acid group refers to a group that dissociates protons, and a salt thereof. Specific examples thereof include a carboxyl group, a sulfo group, and a phosphonic acid group.

The acid value in the present invention refers to the number of millimoles of acid groups per unit mass. The acid value can be measured by a potentiometric titration method. That is, the acid value can be calculated in such a manner that the resin is dissolved in a titration solvent (for example, a 9:1 mixed solvent of propylene glycol monomethyl ether and water) and titrated with a 0.1 mol/L potassium hydroxide aqueous solution, thereby determining the acid value from the titration amount up to the inflection point on the titration curve.

<<<First Form>>>

The resin of the third aspect preferably contains at least one of a repeating unit represented by General Formula (10) or a repeating unit represented by General Formula (11).

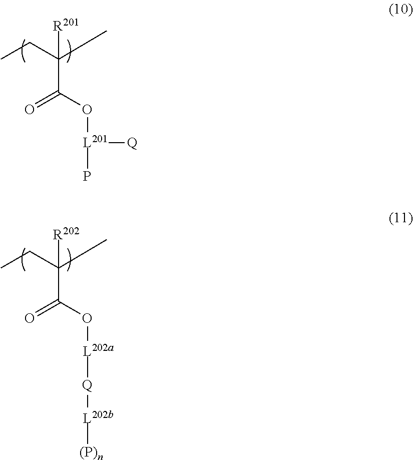

In General Formulae (10) and (11), R²⁰¹ and R²⁰² each represent a hydrogen atom, a methyl group, or a hydroxymethyl group, L²⁰¹ represents a trivalent linking group, L^{202a} represents a single bond or a divalent linking group, L^{202b} represents a single bond, a divalent linking group, or a trivalent linking group, P represents a radical reactive group, Q represents a nonionic hydrophilic group, and n is 1 or 2.

R²⁰¹ and R²⁰² each independently represent a hydrogen atom, a methyl group, or a hydroxymethyl group, preferably a hydrogen atom or a methyl group, and more preferably a methyl group.

L²⁰¹ represents a trivalent linking group and is an aliphatic group, an alicyclic group, an aromatic group, or a trivalent group formed by combining these groups, and may contain an ester bond, an ether bond, a sulfide bond, and a nitrogen atom. The number of carbon atoms in the trivalent linking group is preferably 1 to 9.

L^{202a} represents a single bond or a divalent linking group. The divalent linking group is an alkylene group, a cycloalkylene group, an arylene group, or a divalent group formed by combining these groups, and may contain an ester bond, an ether bond, and a sulfide bond. The number of carbon atoms in the divalent linking group is preferably 1 to 20 and more preferably 1 to 8.

L^{202b} represents a single bond, a divalent linking group, or a trivalent linking group. The divalent linking group represented by L^{202b} has the same definition as the divalent linking group represented by L^{202a}, and a preferred range thereof is also the same. The trivalent linking group represented by L^{202b} has the same definition as the trivalent linking group represented by L²⁰¹, and a preferred range thereof is also the same.

P represents a radical reactive group, and examples thereof include a (meth)acryloyl group, a maleimide group, an allyl group, and a vinyl group, among which a (meth)acryloyl group, an allyl group, or a vinyl group is preferable, and a (meth)acryloyl group is more preferable.

Q represents a nonionic hydrophilic group and has the same definition as the nonionic hydrophilic group exemplified above, and the same applies to the preferred nonionic hydrophilic group.

n is 1 or 2 and preferably 1.

L²⁰¹, L^{202a}, and L^{202b} do not contain a radical reactive group and a nonionic hydrophilic group.

The resin of the third aspect may further have a repeating unit represented by at least one of General Formulae (12) or (13).

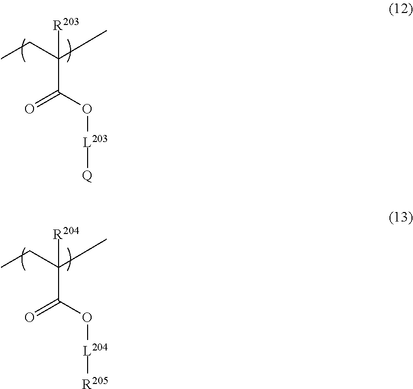

In General Formulae (12) and (13), R²⁰³ and R²⁰⁴ each represent a hydrogen atom, a methyl group, or a hydroxymethyl group, L²⁰³ and L²⁰⁴ each represent a single bond or a divalent linking group, Q represents a nonionic hydrophilic group, and R²⁰⁵ represents an aliphatic group having 1 to 12 carbon atoms, an alicyclic group having 3 to 12 carbon atoms, or an aromatic group having 6 to 12 carbon atoms.

R²⁰³ and R²⁰⁴ each represent a hydrogen atom, a methyl group, or a hydroxymethyl group, preferably a hydrogen atom or a methyl group, and more preferably a methyl group.

R²⁰⁵ represents an aliphatic group having 1 to 12 carbon atoms, an alicyclic group having 1 to 12 carbon atoms, or an aromatic group having 1 to 12 carbon atoms.

Examples of the aliphatic group having 1 to 12 carbon atoms include alkyl groups having 1 to 12 carbon atoms (for example, a methyl group, an ethyl group, a propyl group, an isopropyl group, a butyl group, an isobutyl group, a t-butyl group, a pentyl group, an isopentyl group, a neopentyl group, a hexyl group, a heptyl group, an octyl group, a 2-ethylhexyl group, a 3,3,5-trimethylhexyl group, an isooctyl group, a nonyl group, an isononyl group, a decyl group, an isodecyl group, an undecyl group, and a dodecyl group).

Examples of the alicyclic group having 3 to 12 carbon atoms include cycloalkyl groups having 3 to 12 carbon atoms (for example, a cyclopentyl group, a cyclohexyl group, a norbornyl group, an isobornyl group, an adamantyl group, and a tricyclodecanyl group).

Examples of the aromatic group having 6 to 12 carbon atoms include a phenyl group, a naphthyl group, and a biphenyl group. Among them, a phenyl group or a naphthyl group is preferable.

The aliphatic group, alicyclic group and aromatic group may have a substituent.

L²⁰³ and L²⁰⁴ each represent a single bond or a divalent linking group. The divalent linking group has the same definition as the divalent linking group represented by L^{202a} in General Formula (11), and a preferred range thereof is also the same.

Q represents a nonionic hydrophilic group and has the same definition as the nonionic hydrophilic group exemplified above, and the same applies to preferred nonionic hydrophilic groups.

L²⁰³ and L²⁰⁴ may be an aspect which is free of a radical reactive group and a nonionic hydrophilic group.

Examples of the repeating unit having a nonionic hydrophilic group include those described in paragraph “0036” of JP2014-24322A, the contents of which are incorporated herein by reference in its entirety.

Specific examples of the resin include those described in paragraphs “0038” and “0039” of JP2014-24322A, the contents of which are incorporated herein by reference in its entirety.

<<<Second Form>>>

The resin of the third aspect preferably has a cyclic substituent having a carbonyl group, as a nonionic hydrophilic group, in the ring structure thereof.

Examples of the cyclic substituent having a carbonyl group in the ring structure thereof include a lactone group (cyclic ester group), a cyclic carbonate group, a cyclic ketone group, a cyclic amide (lactam) group, a cyclic urethane group, a cyclic urea group, a cyclic dicarboxylic acid anhydride group, and a cyclic imide group. Among them, a lactone group or a cyclic carbonate group is preferable, and a lactone group is particularly preferable.

The lactone group is a residue formed by removing one hydrogen atom from the lactone structure. A preferred lactone structure is a 5- to 7-membered ring lactone structure. Specific examples of the lactone group include the structures described in paragraphs “0048” and “0049” of JP2014-024322A, the contents of which are incorporated herein by reference in its entirety.

The cyclic carbonate group is a residue formed by removing one hydrogen atom from the cyclic carbonate structure. A preferred structure is a 5-membered or 6-membered ring structure. Specific examples of the cyclic carbonate group include the structures described in paragraph “0052” of JP2014-024322A, the contents of which are incorporated herein by reference in its entirety.

The resin may contain a radical reactive group and a cyclic substituent having a carbonyl group in the ring structure in the same repeating unit or in separate repeating units, but it is preferably a copolymer having a repeating unit having a radical reactive group (for example, a repeating unit represented by General Formula (14)) and a repeating unit having a cyclic substituent having a carbonyl group in the ring structure (for example, a repeating unit represented by General Formula (15)).

The ratio of the repeating unit containing a radical reactive group (for example, a repeating unit represented by General Formula (14)) is preferably 20 to 95 mol %, more preferably 30 to 90 mol %, still more preferably 40 to 85 mol %, and particularly preferably 50 to 80 mol %, with respect to the total repeating units.

The ratio of the repeating unit having a cyclic substituent having a carbonyl group in the ring structure (for example, a repeating unit represented by General Formula (15)) is preferably 5 to 80 mol %, more preferably 10 to 70 mol %, still more preferably 15 to 60 mol %, and particularly preferably 20 to 50 mol %, with respect to the total repeating units.

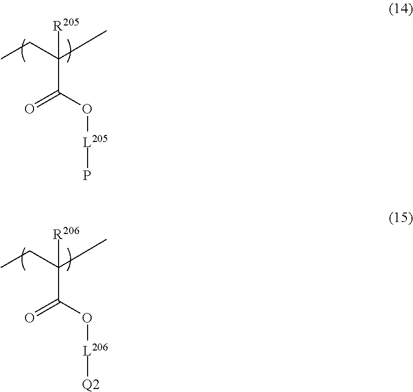

In General Formulae (14) and (15), R²⁰⁵ and R²⁰⁶ each represent a hydrogen atom, a methyl group, or a hydroxymethyl group, L²⁰⁵ and L²⁰⁶ each represent a single bond or a divalent linking group, P represents a radical reactive group, and Q2 represents a cyclic substituent having a carbonyl group in the ring structure thereof.

R²⁰⁵ and R²⁰⁶ each represent a hydrogen atom, a methyl group, or a hydroxymethyl group, preferably a hydrogen atom or a methyl group, and more preferably a methyl group.

L²⁰⁵ and L²⁰⁶ each represent a single bond or a divalent linking group having 1 to 10 carbon atoms. The divalent linking group is an alkylene group which is unsubstituted or substituted with a hydroxyl group, and may contain an ether bond, an ester bond, an amide bond, or a urethane bond.

Further, L²⁰⁵ and L²⁰⁶ may be an aspect which is free of a radical reactive group and a nonionic hydrophilic group.

P represents a radical reactive group, and examples thereof include a (meth)acryloyl group, a maleimide group, an allyl group, and a vinyl group, among which a (meth)acryloyl group, an allyl group, or a vinyl group is preferable, and a (meth)acryloyl group is more preferable.

Q2 represents a cyclic substituent having a carbonyl group in the ring structure thereof. Q2 has the same definition as the cyclic substituent exemplified above, and a preferred range thereof is also the same.

The resin of the third aspect may contain the other repeating unit which does not contain both a radical reactive group and a cyclic substituent having a carbonyl group in the ring structure. The ratio of the other repeating unit in the resin is preferably 50 mol % or less.

Examples of the repeating unit having a lactone structure include those described in paragraphs “0050” and “0051” of JP2014-24322A, the contents of which are incorporated herein by reference in its entirety.

Examples of the repeating unit having a cyclic carbonate structure include those described in paragraph “0053” of JP2014-24322A, the contents of which are incorporated herein by reference in its entirety.

Specific examples of the resin of the third aspect include those described in paragraphs “0054” and “0055” of JP2014-24322A, the contents of which are incorporated herein by reference in its entirety.

<<Resin of Fourth Aspect>>

The resin of the fourth aspect is a resin having a radical reactive group and a group having an interaction with a base material in the side chain thereof.

In the present specification, the “group having an interaction with a base material” is a group capable of acting chemically or physically to bind to the base material. The base material may be, for example, a base material which will be described later.

Examples of the group having an interaction with a base material include a carboxyl group, an ether group, an amino group, an imino group, a morpholino group, an amide group, an imide group, a thiol group, a thioether group, an alkoxysilyl group, and a functional group having these groups in the ring structure thereof, among which a carboxyl group is preferable.

The resin of the fourth aspect may be, for example, a resin containing at least one of Structure A or B given below. In the following structures, x and y represent the number of repeating units, and the sum of x and y is preferably 8 to 11.

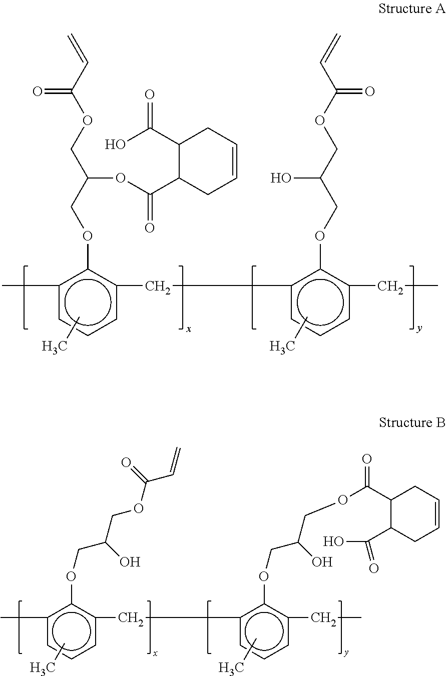

The commercially available product of the resin containing at least one of Structure A or B may be, for example, ISORAD (registered trademark) 501 (manufactured by Schenectady International, Inc.).

In the present invention, the weight-average molecular weight of the resin is preferably 5,000 to 50,000. The lower limit of the weight-average molecular weight of the resin is more preferably 8,000 or more and still more preferably 10,000 or more. The upper limit of the weight-average molecular weight of the resin is more preferably 35,000 or less and still more preferably 25,000 or less. By setting the weight-average molecular weight to be within the above-specified range, it is possible to ensure good film formability.

The content of the resin in the resin composition for underlayer film formation according to the present invention is preferably 70 to 99.99 mass % with respect to the solid content of the resin composition for underlayer film formation. The lower limit of the content of the resin is, for example, more preferably 80 mass % or more, still more preferably 85 mass % or more, and particularly preferably 90 mass % or more. The upper limit of the content of the resin is, for example, more preferably 99.95 mass % or less and still more preferably 99.9 mass % or less.

Further, the content of the resin is preferably 0.01 to 5 mass %, more preferably 0.05 to 4 mass %, and still more preferably 0.1 to 3 mass %, with respect to the total amount of the resin composition for underlayer film formation.

If the content of the resin is within the above-specified range, it is easy to form an underlayer film having better adhesiveness and surface state.

The resins may be used alone or in combination of two or more thereof. In the case where two or more resins are used, it is preferred that the total amount of two or more resins is within the above-specified range.

<<Solvent>>

The resin composition for underlayer film formation according to the present invention contains a solvent. The solvent is preferably an organic solvent having a boiling point of 80° C. to 200° C. at normal pressures. Any organic solvent may be used as long as it is a solvent capable of dissolving individual components constituting a resin composition for underlayer film formation. Examples of the solvent include organic solvents having any one or more of an ester group, a carbonyl group, a hydroxyl group, and an ether group. More specifically, preferred examples of the organic solvent include propylene glycol monomethyl ether acetate (PGMEA), ethoxyethyl propionate, cyclohexanone, 2-heptanone, γ-butyrolactone, butyl acetate, propylene glycol monomethyl ether, and ethyl lactate. Among them, PGMEA, ethoxyethyl propionate, and 2-heptanone are more preferable, and PGMEA is particularly preferable. Two or more organic solvents may be used in combination thereof. A mixed solvent of an organic solvent having a hydroxyl group and an organic solvent having no hydroxyl group is also preferable.

The content of the solvent in the resin composition for underlayer film formation is appropriately adjusted depending on the viscosity of the composition and a desired film thickness of an underlayer film From the viewpoint of coatability, the solvent is contained in the range of preferably 95 to 99.9 mass %, more preferably 97 to 99.9 mass %, still more preferably 98 to 99.9 mass %, even more preferably 99 to 99.9 mass %, and most preferably 99.5 to 99.9 mass %%, with respect to the total amount of the resin composition for underlayer film formation.

<<Water>>

The resin composition for underlayer film formation according to the present invention may contain water. Incorporation of water tends to result in an improved affinity with a base material, and further improved adhesiveness of an underlayer film to a base material.

In the case where the resin composition for underlayer film formation according to the present invention contains water, the content of water is preferably 0.01 to 0.3 mass % with respect to the total amount of the resin composition for underlayer film formation. The lower limit value of the content of water is more preferably 0.02 mass % or more and still more preferably 0.03 mass % or more. The upper limit value of the content of water is, for example, more preferably 0.25 mass % or less and still more preferably 0.2 mass % or less. If the content of water is within the above-specified range, the above-described effect is easily obtained.

Further, the resin composition for underlayer film formation according to the present invention may be a composition which is substantially free of water. As for the phrase “substantially free of water”, the content of water is, for example, 0.005 mass % or less and preferably 0.001 mass % or less, with respect to the total amount of the resin composition for underlayer film formation.

<<Nonionic Surfactant>>

The resin composition for underlayer film formation according to the present invention preferably contains a surfactant. Incorporation of a surfactant results in an improved coatability of the resin composition for underlayer film formation and an improved surface state of the underlayer film.

The surfactant is preferably a nonionic surfactant.

In the present invention, the nonionic surfactant is a compound having at least one hydrophobic portion and at least one nonionic hydrophilic portion. The hydrophobic portion and the hydrophilic portion may be respectively present at the terminal of a molecule or may be present within the molecule. The hydrophobic portion is formed of a hydrophobic group selected from a hydrocarbon group, a fluorine-containing group, and an Si-containing group, and the number of carbon atoms in the hydrophobic portion is preferably 1 to 25, more preferably 2 to 15, still more preferably 4 to 10, and most preferably 5 to 8. The nonionic hydrophilic portion has at least one group selected from the group consisting of an alcoholic hydroxyl group, a phenolic hydroxyl group, an ether group (preferably a polyoxyalkylene group or a cyclic ether group), an amido group, an imido group, a ureido group, a urethane group, a cyano group, a sulfonamido group, a lactone group, a lactam group, and a cyclocarbonate group. Among them, preferred is an alcoholic hydroxyl group, a polyoxyalkylene group, or an amido group, and particularly preferred is a polyoxyalkylene group. The nonionic surfactant may be any nonionic surfactant of a hydrocarbon-based nonionic surfactant, a fluorine-based nonionic surfactant, an Si-based nonionic surfactant, or a fluorine.Si-based nonionic surfactant, but it is preferably a fluorine-based or Si-based nonionic surfactant and more preferably a fluorine-based nonionic surfactant. Here, the “fluorine.Si-based nonionic surfactant” refers to a nonionic surfactant satisfying requirements of both a fluorine-based nonionic surfactant and an Si-based nonionic surfactant. By using such a nonionic surfactant, it is easy to obtain the effect described above. Further, it is capable of improving coating uniformity, and therefore a good coating film is obtained in coating using a spin coater or a slit scanning coater.

Further, in the present invention, the content ratio of fluorine in the fluorine-based nonionic surfactant is preferably within the range of 6 to 70 mass %, from the viewpoint of compatibility between the resin and the fluorine-based nonionic surfactant, coatability of a thin film having a thickness of several nm to several tens of nm, roughness reduction of a coating film surface, and fluidity of an imprint layer to be laminated after formation of a film. An example of a more specific compound structure is preferably a fluorine-based nonionic surfactant having a fluorine-containing alkyl group and a polyoxyalkylene group. The number of carbon atoms in the fluorine-containing alkyl group is preferably 1 to 25, more preferably 2 to 15, still more preferably 4 to 10, and most preferably 5 to 8. The polyoxyalkylene group is preferably a polyoxyethylene group or a polyoxypropylene group. The repeat number of the polyoxyalkylene group is preferably 2 to 30, more preferably 6 to 20, and still more preferably 8 to 15.

The fluorine-based nonionic surfactant is preferably a compound represented by General Formula (W1) or (W2).

Rf¹-(L¹)ₐ-(OCₚ₁H₂ₚ₁)_{q1}—O—R General Formula (W1)

Rf²¹-(L²¹)_{b}-(OCₚ₂H₂ₚ₂)_{q2}—O-(L²²)_{c}-Rf²² General Formula (W2)

Here, Rf¹, Rf²¹, and Rf²² represent a fluorine-containing group having 1 to 25 carbon atoms, and R represents a hydrogen atom or an alkyl group having 1 to 8 carbon atoms, an alkenyl group having 2 to 8 carbon atoms, or an aryl group having 6 to 8 carbon atoms.

L¹ and L²¹ represent a single bond, or a divalent linking group selected from —CH(OH)CH₂—, —O(C═O)CH₂—, and —OCH₂(C═O)—. L²² represents a single bond, or a divalent linking group selected from —CH₂CH(OH)—, —CH₂(C═O)O—, and —(C═O)CH₂O—.

a, b, and c represent 0 or 1.

p1 and p2 represent an integer of 2 to 4, and q1 and q2 represent an integer of 2 to 30.

Rf¹, Rf²¹, and Rf²² represent a fluorine-containing group having 1 to 25 carbon atoms. Examples of the fluorine-containing group include a perfluoroalkyl group, a perfluoroalkenyl group, a ω-H-perfluoroalkyl group, and a perfluoropolyether group. The number of carbon atoms in the fluorine-containing group is 1 to 25, preferably 2 to 15, more preferably 4 to 10, and still more preferably 5 to 8. Specific examples of Rf¹, Rf²¹, and Rf²² include CF₃CH₂—, CF₃CF₂CH₂—, CF₃(CF₂)₂CH₂—, CF₃(CF₂)₃CH₂CH₂—, CF₃(CF₂)₄CH₂CH₂CH₂—, CF₃(CF₂)₄CH₂—, CF₃(CF₂)₅CH₂CH₂—, CF₃(CF₂)₅CH₂CH₂CH₂—, (CF₃)₂CH—, (CF₃)₂C(CH₃)CH₂—, (CF₃)₂CF(CF₂)₂CH₂CH₂—, (CF₃)₂CF(CF₂)₄CH₂CH₂—, H(CF₂)₂CH₂—, H(CF₂)₄CH₂—, H(CF₂)₆CH₂—, H(CF₂)₈CH₂—, (CF₃)₂C═C(CF₂CF₃)—, and {(CF₃CF₂)₂CF}₂C═C(CF₃)—.

Among them, preferred is CF₃(CF₂)₂CH₂—, CF₃(CF₂)₃CH₂CH₂—, CF₃(CF₂)₄CH₂—, CF₃(CF₂)₅CH₂CH₂—, or H(CF₂)₆CH₂—, and particularly preferred is CF₃(CF₂)₅CH₂CH₂—.

R represents a hydrogen atom, an alkyl group having 1 to 8 carbon atoms, an alkenyl group having 2 to 8 carbon atoms, or an aryl group having 6 to 8 carbon atoms. Among them, preferred is an alkyl group having 1 to 8 carbon atoms.

Specific examples of R include a hydrogen atom, a methyl group, an ethyl group, an n-propyl group, an isopropyl group, an n-butyl group, an isobutyl group, a sec-butyl group, a tert-butyl group, an n-pentyl group, an isopentyl group, a neopentyl group, a hexyl group, a heptyl group, an octyl group, a cyclopentyl group, a cyclohexyl group, an allyl group, a phenyl group, a benzyl group, and a phenethyl group. Among them, more preferred is a hydrogen atom, a methyl group, an n-butyl group, an allyl group, a phenyl group, or a benzyl group, and particularly preferred is a hydrogen atom or a methyl group.

The polyoxyalkylene group (—(OCₚ₁H₂ₚ₁)_{q1}— and —(OCₚ₂H₂ₚ₂)_{q2}—) is selected from a polyoxyethylene group, a polyoxypropylene group, a polyoxybutylene group, and a poly(oxyethylene/oxypropylene) group, and is more preferably a polyoxyethylene group or a polyoxypropylene group and most preferably a polyoxyethylene group. The repeat number q1 or q2 is, on average, 2 to 30, preferably 6 to 20, and more preferably 8 to 16.

Specific compound examples of the fluorine-based nonionic surfactant represented by General Formulae (W1) and (W2) include the following compounds.

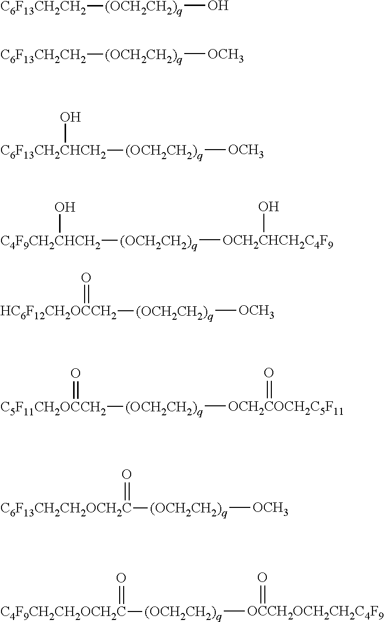

Examples of commercially available fluorine-based nonionic surfactant include FLUORAD FC-4430 and FC-4431 (manufactured by Sumitomo 3M Limited), SURFLON S-241, S-242, and S-243 (manufactured by Asahi Glass Co., Ltd.), EFTOP EF-PN31M-03, EF-PN31M-04, EF-PN31M-05, EF-PN31M-06, and MF-100 (manufactured by Mitsubishi Materials Electronic Chemicals Co., Ltd.), POLYFOX PF-636, PF-6320, PF-656, and PF-6520 (manufactured by OMNOVA Solutions Inc.), FTERGENT 250, 251, 222F, 212M, and DFX-18 (manufactured by Neos Company Limited), UNIDYNE DS-401, DS-403, DS-406, DS-451, and DSN-403N (manufactured by Daikin Industries Ltd.), MEGAFACE F-430, F-444, F-477, F-553, F-556, F-557, F-559, F-562, F-565, F-567, F-569, and R-40 (manufactured by DIC Corporation), and CAPSTONE FS-3100 and ZONYL FSO-100 (manufactured by E.I. du Pont de Nemours and Company Co., Ltd.).

More preferred examples of the fluorine-based nonionic surfactant include POLYFOX PF-6520 and PF-6320, MEGAFACE F-444, and CAPSTONE FS-3100.

Examples of the hydrocarbon-based nonionic surfactant include polyoxyalkylene alkyl ethers and polyoxyalkylene aryl ethers, sorbitan fatty acid esters, and fatty acid alkanol amides. Specific examples of the polyoxyalkylene alkyl ethers and polyoxyalkylene aryl ethers include polyoxyethylene octyl ether, polyoxyethylene 2-ethylhexyl ether, polyoxyethylene lauryl ether, polyoxyethylene cetyl ether, polyoxyethylene oleyl ether, polyoxyethylene nonylphenyl ether, and polyoxyethylene naphthyl ether. As a commercially available product thereof, Newcol series (for example, Newcol 1008) manufactured by Nippon Nyukazai Co., Ltd. may be mentioned. Specific examples of the sorbitan fatty acid esters include sorbitan laurate and sorbitan oleate, polyoxyethylene sorbitan laurate, and polyoxyethylene sorbitan oleate. Specific examples of the fatty acid alkanol amides include lauric acid diethanolamide, and oleic acid diethanolamide.

Commercially available examples of the Si-based nonionic surfactant include SI-10 series (manufactured by Takemoto Oil & Fat Co., Ltd.), SH-3746, SH-3749, SH-3771, SH-8400, and TH-8700 (manufactured by Dow Corning Toray Co., Ltd.), and Shin-Etsu silicones KP-322, KP-341, KF-351, KF-352, KF-353, KF-354L, KF-355A, and KF-615A (manufactured by Shin-Etsu Chemical Co., Ltd).

Commercially available examples of the fluorine.Si-based nonionic surfactant include X-70-090, X-70-091, X-70-092, X-70-093, and FL-5 (manufactured by Shin-Etsu Chemical Co., Ltd.), and MEGAFACE R-08 and XRB-4 (manufactured by DIC Corporation).

In the case where the resin composition for underlayer film formation according to the present invention contains a surfactant, the content of the surfactant is preferably 0.01 to 25 parts by mass with respect to 100 parts by mass of the resin. The lower limit value of the content of the surfactant is, for example, more preferably 0.05 parts by mass or more, and still more preferably 0.1 parts by mass or more. The upper limit value of the content of the surfactant is, for example, more preferably 20 parts by mass or less, and still more preferably 15 parts by mass or less. If the content of the surfactant is within the above-specified range, it is easy to obtain the effect described above.

The surfactants may be used alone or in combination of two or more thereof. In the case where two or more surfactants are used in combination, the total amount thereof is within the above-specified range.

<<Acid Catalyst>>

The resin composition for underlayer film formation according to the present invention also preferably contains an acid catalyst. By including an acid catalyst, it is possible to cure the resin composition for underlayer film formation at a relatively low heating temperature (also referred to as a baking temperature).

Examples of the acid catalyst include an acid and a thermal acid generator.

Examples of the acid include p-toluenesulfonic acid, 10-camphorsulfonic acid, and perfluorobutane sulfonic acid.

The thermal acid generator is preferably a compound that generates an acid at 100° C. to 180° C. (more preferably, 120° C. to 180° C., and still more preferably 120° C. to 160° C.). By setting the acid generation temperature to 100° C. or more, it is possible to ensure the temporal stability of the resin composition for underlayer film formation.

Examples of the thermal acid generator include isopropyl-p-toluenesulfonate, cyclohexyl-p-toluenesulfonate, an aromatic sulfonium salt compound named SAN-AID SI series manufactured by Sanshin Chemical Industry Co., Ltd., and CYCAT 4040 (manufactured by Cytec Industries Co., Ltd.).

In the case of containing an acid catalyst, the acid catalyst is contained in an amount of preferably 0.1 to 10 parts by mass with respect to 100 parts by mass of the resin. The lower limit of the acid catalyst is more preferably 0.5 parts by mass or more. The upper limit of the acid catalyst is more preferably 5 parts by mass or less.

The content of the acid catalyst is preferably 0.0005 to 0.1 mass % with respect to the total amount of the resin composition for underlayer film formation. The lower limit of the acid catalyst is more preferably 0.0005 mass % or more. The upper limit of the acid catalyst is more preferably 0.01 mass % or less, and still more preferably 0.005 mass % or less.

In the present invention, as an acid catalyst, the acid and the thermal acid generator may be used in combination or may be respectively used alone. In addition, acids and thermal acid generators may be respectively used alone or in combination of two or more thereof.

<<Other Components>>

The resin composition for underlayer film formation according to the present invention may contain a crosslinking agent, a polymerization inhibitor, and the like as other components. The amount of these components to be blended is preferably 50 mass % or less, more preferably 30 mass % or less, and still more preferably 10 mass % or less, with respect to the total components of the resin composition for underlayer film formation excluding the solvent. It is, however, particularly preferable to contain substantially no other components. The expression of “to contain substantially no other components” as used herein means that the other components are only, for example, additives such as a reactant, a catalyst, and a polymerization inhibitor used for synthesis of the resin, and impurities derived from reaction by-products, and are not intentionally added to the resin composition for underlayer film formation. More specifically, the content of the other components may be 5 mass % or less, and further 1 mass % or less.

<<<Crosslinking Agent>>>

The crosslinking agent is preferably a cation-polymerizable compound such as an epoxy compound, an oxetane compound, a methylol compound, a methylol ether compound, or a vinyl ether compound.

Examples of the epoxy compound include EPOLITE manufactured by Kyoeisha Chemical Co., Ltd.; DENACOL EX manufactured by Nagase ChemteX Corporation; EOCN, EPPN, NC, BREN, GAN, GOT, AK, and RE Series manufactured by Nippon Kayaku Co., Ltd.; EPIKOTE manufactured by Japan Epoxy Resins Co., Ltd.; EPICLON manufactured by DIC Corporation; and TEPIC Series manufactured by Nissan Chemical Industries, Ltd. Two or more thereof may be used in combination.

Examples of the oxetane compound include ETERNACOLL OXBP, OXTP, and OXIPA manufactured by Ube Industries, Ltd.; and ARON oxetane OXT-121 and OXT-221 manufactured by Toagosei Co., Ltd.

Examples of the vinyl ether compound include VEctomer Series manufactured by Allied Signal, Inc.

Examples of the methylol compound and methylol ether compound include a urea resin, a glycouril resin, a melamine resin, a guanamine resin, and a phenol resin. Specific examples thereof include NIKALAC MX-270, MX-280, MX-290, MW-390, and BX-4000 manufactured by Sanwa Chemical Co., Ltd; and CYMEL 301, 303 ULF, 350, and 1123 manufactured by Cytec Industries Co., Ltd.

<<<Polymerization Inhibitor>>>

The preservation stability can be improved by including a polymerization inhibitor in a resin composition for underlayer film formation. Examples of the polymerization inhibitor include hydroquinone, p-methoxyphenol, di-tert-butyl-p-cresol, pyrogallol, tert-butylcatechol, benzoquinone, 4,4′-thiobis(3-methyl-6-tert-butylphenol), 2,2′-methylenebis(4-methyl-6-tert-butylphenol), N-nitrosophenylhydroxylamine cerous salt, phenothiazine, phenoxazine, 4-methoxynaphthol, 2,2,6,6-tetramethylpiperidine-1-oxyl free radical, 2,2,6,6-tetramethylpiperidine, 4-hydroxy-2,2,6,6-tetramethylpiperidine-1-oxyl free radical, nitrobenzene, and dimethylaniline. Among them, phenothiazine, 4-methoxynaphthol, 2,2,6,6-tetramethylpiperidine-1-oxyl free radical, 2,2,6,6-tetramethylpiperidine, and 4-hydroxy-2,2,6,6-tetramethylpiperidine-1-oxyl free radical are preferable, since they exhibit polymerization inhibiting effects even under an oxygen-free condition.

<Preparation of Resin Composition for Underlayer Film Formation>

The resin composition for underlayer film formation according to the present invention can be prepared by mixing the above-mentioned individual components. Also, after mixing the individual components, it is preferred to filter the mixture through, for example through a filter. Filtration may be carried out in multiple steps or may be repeated many times. It is also possible to re-filter the filtrate.

Any filter may be used without particular limitation as long as it is conventionally used for filtration or the like. For example, the filter may be a filter made of a fluororesin such as polytetrafluoroethylene (PTFE), a polyamide-based resin such as nylon-6 or nylon-6,6, a polyolefin resin such as polyethylene or polypropylene (PP) (including ones having a high density and an ultra-high molecular weight), or the like. Among these materials, preferred are polypropylene (including high-density polypropylene) and nylon.

The pore size of the filter is suitably, for example, about 0.003 to 5.0 μm. By specifying the pore size of the filter to be in this range, it becomes possible to reliably remove fine foreign materials such as impurities and aggregates contained in the composition, while suppressing filtration clogging.

For the use of filter, different filters may be used in combination. In that case, filtering by a first filter may be carried out only once or two or more times. In a case of filtering two or more times by combining different filters, the pore size for a second or subsequent filtering is preferably made smaller than or equal to that for the first filtering. In addition, first filters having a different pore size in the above-mentioned range may be used in combination. The pore size herein can be set by referring to nominal values of filter manufacturers. Commercially available filters can be selected from various filters supplied by, for example, Nihon Pall Ltd., Advantec Toyo Kaisha, Ltd., Nihon Entegris K.K. (formerly Nihon Mykrolis K.K.) or Kitz Micro Filter Corporation.

<Photocurable Composition>

The photocurable composition (preferably, a photocurable composition for imprints) used together with the resin composition for underlayer film formation according to the present invention generally contains a polymerizable compound and a photopolymerization initiator.

<<Polymerizable Compound>>

The polymerizable compound is preferably a polymerizable monomer. Examples thereof include a polymerizable monomer having 1 to 6 groups containing an ethylenically unsaturated bond; an epoxy compound; an oxetane compound; a vinyl ether compound; a styrene derivative; and propenyl ether and butenyl ether.

The polymerizable compound preferably has a polymerizable group which is polymerizable with the polymerizable group of the resin contained in the resin composition for underlayer film formation according to the present invention. Among them, (meth)acrylate is preferable. Specific examples thereof include those described in paragraphs “0020” to “0098” of JP2011-231308A, the contents of which are incorporated herein by reference in its entirety. Examples of commercially available products include VISCOAT #192 (manufactured by Osaka Organic Chemical Industry) and R-1620 (manufactured by Daikin Industries, Ltd.).

The content of the polymerizable compound is, for example, preferably 50 to 99 mass %, more preferably 60 to 99 mass %, and still more preferably 70 to 99 mass %, with respect to the solid content of the photocurable composition. In the case where two or more polymerizable compounds are used, it is preferred that the total amount thereof is within the above-specified range.

The polymerizable compound is preferably a polymerizable compound having at least one of an alicyclic hydrocarbon group or an aromatic group, and in addition, more preferably includes a polymerizable compound having at least one of an alicyclic hydrocarbon group or an aromatic group and a polymerizable compound having at least one of a silicon atom or a fluorine atom. The total content of the polymerizable compound having at least one of an alicyclic hydrocarbon group or an aromatic group preferably accounts for 30 to 100 mass %, more preferably 50 to 100 mass %, and still more preferably 70 to 100 mass % of the total polymerizable compounds. The molecular weight of the polymerizable compound is preferably less than 1,000.

A further preferred aspect is a case where the content of the (meth)acrylate polymerizable compound having an aromatic group, used as the polymerizable compound, is preferably 50 to 100 mass %, more preferably 70 to 100 mass %, and particularly preferably 90 to 100 mass % of the total polymerizable compounds.

A particularly preferred aspect is a case where the content of the polymerizable compound (1) described below is 0 to 80 mass % (more preferably 20 to 70 mass %) of the total polymerizable compounds, the content of the polymerizable compound (2) described below is 20 to 100 mass % (more preferably 50 to 100 mass %) of the total polymerizable compounds, and the content of the polymerizable compound (3) described below is 0 to 10 mass % (more preferably 0.1 to 6 mass %) of the total polymerizable compounds:

(1) a polymerizable compound having an aromatic group (preferably a phenyl group or a naphthyl group, and more preferably a naphthyl group) and a (meth)acryloyloxy group;

(2) a polymerizable compound having an aromatic group (preferably a phenyl group or a naphthyl group, and more preferably a phenyl group), and two (meth)acrylate groups; and

(3) a polymerizable compound having at least one of a fluorine atom or a silicon atom (more preferably a fluorine atom), and a (meth)acryloyloxy group.

In a photocurable composition for imprints, the content of a polymerizable compound having a viscosity at 25° C. of less than 5 mPa·s is preferably 50 mass % or less, more preferably 30 mass % or less, and still more preferably 10 mass % or less, with respect to the total polymerizable compounds. By setting the content of a polymerizable compound to the above-specified range, inkjet ejection stability may be improved, and thereby defects in imprint transfer may be reduced.

<<Photopolymerization Initiator>>

The photopolymerization initiator may be any compound which generates an active species capable of polymerizing the above-described polymerizable compound under photoirradiation. The photopolymerization initiator is preferably a radical polymerization initiator or a cation polymerization initiator, and more preferably a radical polymerization initiator. In the present invention, a plurality of photopolymerization initiators may be used in combination.

The radical photopolymerization initiator may be, for example, commercially available initiators. Those described, for example, in paragraph “0091” of JP2008-105414A may be preferably used. Among them, an acetophenone-based compound, an acylphosphine oxide-based compound, and an oxime ester-based compound are preferable from the viewpoints of curing sensitivity and absorption properties. Examples of commercially available products include Irgacure (registered trademark) 907 (manufactured by BASF Corporation).

It is also possible to use an oxime compound having a fluorine atom as a photopolymerization initiator. Specific examples of such a compound include the compounds described in JP2010-262028A, the compounds 24 and 36 to 40 described in paragraph “0345” of JP2014-500852A, and the compound (C-3) described in paragraph “0101” of JP2013-164471A.

The content of the photopolymerization initiator is, for example, preferably 0.01 to 15 mass %, more preferably 0.1 to 12 mass %, and still more preferably 0.2 to 7 mass %, with respect to the solid content of the photocurable composition. In the case where two or more photopolymerization initiators are used, the total content thereof preferably falls in the above-specified ranges. In the case where the content of the photopolymerization initiator is 0.01 mass % or more, there will be a tendency for improvements in sensitivity (fast curability), resolution, line edge roughness, and coating film strength, which is preferable. On the other hand, in the case where the content of the photopolymerization initiator is 15 mass % or less, there will be trends of improvements in light transmittance, colorability, and handleability, which is preferable.

<<Surfactant>>

The photocurable composition preferably contains a surfactant.

The surfactant may be, for example, those surfactants described for the resin composition for underlayer film formation as described above. Examples of the surfactant usable in the present invention may be referred to paragraph “0097” of JP2008-105414A, the contents of which are incorporated herein by reference in its entirety. The surfactant is also commercially available, and an example thereof includes PF-636 (manufactured by OMNOVA Solutions Inc.).

The content of the surfactant is, for example, 0.001 to 5 mass %, preferably 0.002 to 4 mass %, and more preferably 0.005 to 3 mass %, with respect to the solid content of the photocurable composition. In the case where two or more surfactants are used, the total content thereof preferably falls within the above-specified ranges. If the content of the surfactant falls within the range of 0.001 to 5 mass % in the composition, the effect on the uniformity of coating will be satisfactory.

<<Non-Polymerizable Compound>>

The photocurable composition may contain a non-polymerizable compound which has, at the terminal thereof, at least one hydroxyl group or a polyalkylene glycol structure formed by etherifying the hydroxyl group, and contains substantially no fluorine atom and silicon atom.

The content of the non-polymerizable compound is, for example, preferably 0.1 to 20 mass %, more preferably 0.2 to 10 mass %, still more preferably 0.5 to 5 mass %, and even more preferably 0.5 to 3 mass %, with respect to the total solid content of the photocurable composition.

<<Antioxidant>>

The photocurable composition preferably contains an antioxidant.

The antioxidant is for preventing fading by heat or photoirradiation, and for preventing fading by various oxidized gases such as ozone, active hydrogen, NOx, and SOx (x is an integer). Incorporation of an antioxidant into the photocurable composition brings about advantages that the cured film is prevented from being colored and the film thickness is prevented from being reduced due to decomposition of the cured film.

Examples of the antioxidant includes hydrazides, hindered amine-based antioxidants, nitrogen-containing heterocyclic mercapto-based compounds, thioether-based antioxidants, hindered phenol-based antioxidants, ascorbic acids, zinc sulfate, thiocyanates, thiourea derivatives, saccharides, nitrites, sulfites, thiosulfates, and hydroxylamine derivatives. Among them, particularly preferred are hindered phenol-based antioxidants and thioether-based antioxidants from the viewpoint of their effect of preventing cured film coloration and preventing film thickness reduction.

Commercial products of the antioxidant include trade name Irganox (registered trademark) 1010, 1035, 1076, and 1222 (all manufactured by BASF Corporation); trade name Antigene P, 3C, FR, SUMILIZER S, and SUMILIZER GA80 (manufactured by Sumitomo Chemical Co., Ltd.), and trade name ADEKASTAB AO70, AO80, and AO503 (manufactured by Adeka). These antioxidants may be used alone or in combination thereof.

The content of the antioxidant is, for example, 0.01 to 10 mass %, and preferably 0.2 to 5 mass %, with respect to the polymerizable compound. In the case where two or more antioxidants are used, the total amount thereof preferably falls within the above-specified range.

<<Polymerization Inhibitor>>

The photocurable composition preferably contains a polymerization inhibitor. By including the polymerization inhibitor, there is a tendency for suppressing a change in viscosity over time, occurrence of foreign materials and deterioration of pattern formability.

The content of the polymerization inhibitor is, for example, 0.001 to 1 mass %, preferably 0.005 to 0.5 mass %, and more preferably 0.008 to 0.05 mass %, with respect to the polymerizable compound, and a change in viscosity over time can be inhibited while maintaining a high curing sensitivity by blending the polymerization inhibitor in an appropriate amount. The polymerization inhibitor may be contained in the polymerizable compound to be used in advance or may be further added to the photocurable composition.

Specific examples of the polymerization inhibitor may be referred to the description in paragraph “0125” of JP2012-094821A, the contents of which are incorporated herein by reference in its entirety.

<<Solvent>>

The photocurable composition may contain a solvent, if necessary. Examples of the solvent include those described for the above-mentioned resin composition for underlayer film formation.

The content of the solvent in the photocurable composition is appropriately adjusted depending on the viscosity, coatability, and desired film thickness of the photocurable composition. From the viewpoint of improving coatability, the content of the solvent in the photocurable composition may be preferably in the range of 99 mass % or less. In the case where the photocurable composition is applied onto a base material by an inkjet method, it is preferred that the photocurable composition contains substantially no solvent (for example, 3 mass % or less). On the other hand, when a pattern having a film thickness of 500 nm or less is formed by a spin-coating method or the like, the content of the solvent may be 20 to 99 mass %, preferably 40 to 99 mass %, and particularly preferably 70 to 98 mass %.

<<Polymer Component>>

The photocurable composition may further contain a polymer component, from the viewpoint of improving dry etching resistance, imprint suitability, curability, and the like. The polymer component is preferably a polymer having a polymerizable group in the side chain thereof. The weight-average molecular weight of the polymer component is preferably 2,000 to 100,000, and more preferably 5,000 to 50,000, from the viewpoint of compatibility with a polymerizable compound. The content of the polymer component is preferably 0 to 30 mass %, more preferably 0 to 20 mass %, still more preferably 0 to 10 mass %, and most preferably 0 to 2 mass %, with respect to the solid content of the photocurable composition.

In a photocurable composition for imprints, since pattern formability may be improved if the content of a compound having a molecular weight of 2,000 or larger is 30 mass % or less, a lower content of polymer components is preferable, and therefore it is preferred that the photocurable composition contains substantially no polymer components, except for a surfactant or trace amounts of additives.

In addition to the above-mentioned components, the photocurable composition may contain a mold release agent, a silane coupling agent, an ultraviolet absorbing agent, a light stabilizer, an antiaging agent, a plasticizer, an adhesiveness promoter, a thermal polymerization initiator, a colorant, elastomer particles, a photoacid amplifier, a photobase generator, a basic compound, a fluidity controlling agent, an anti-foaming agent, or a dispersant, if desired.

The photocurable composition may be prepared by mixing the individual components described above. Mixing of the individual components is generally carried out in a temperature range of 0° C. to 100° C. After mixing of the individual components, for example, the mixture is preferably filtered through a filter having a pore size of 0.003 to 5.0 um. The filtration may be carried out in a multi-stage manner, or may be repeated a plurality of times. Examples of the filter material and method include those described for the resin composition for underlayer film formation, and a preferred range thereof is also the same.

The viscosity of the photocurable composition is preferably 0.5 to 20 mPa·s at 23° C. The lower limit of the viscosity of the photocurable composition is, for example, more preferably 1 mPa·s or more and still more preferably 5 mPa·s or more. The upper limit of the viscosity of the photocurable composition is, for example, more preferably 15 mPa·s or less and still more preferably 10 mPa·s or less. In the present invention, the value of the viscosity is a value measured by using an E type rotational viscometer RE 85 L manufactured by Toki Sangyo Co., Ltd., a standard cone rotor (1° 34′×R24), setting a rotation speed at 50 rpm, and adjusting a sample cup to a temperature of 23±0.1° C.

<Laminate>

The laminate of the present invention has, on the surface of a base material, an underlayer film formed by curing the above-mentioned resin composition for underlayer film formation according to the present invention.

The thickness of the underlayer film is not particularly limited, but it is preferably 1 to 10 nm, and more preferably 2 to 5 nm.

The base material is not particularly limited and is selectable depending on a variety of applications. Examples of the base material include quartz, glass, an optical film, a ceramic material, an evaporated film, a magnetic film, a reflective film, a metal base material such as Ni, Cu, Cr, or Fe, a paper, Spin On Carbon (SOC), Spin On Glass (SOG), a polymer base material such as a polyester film, a polycarbonate film or a polyimide film, a thin film transistor (TFT) array base material, an electrode plate of plasma display panel (PDP), a conductive base material such as an Indium Tin Oxide (ITO) or metal, an insulating base material, and a base material used in semiconductor manufacturing such as silicon, silicon nitride, polysilicon, silicon oxide or amorphous silicon. In the present invention, an appropriate underlayer film may be formed particularly even when a base material having a small surface energy (for example, about 40 to 60 mJ/m²) is used. Meanwhile, in the case where the base material is intended to be etched, a base material used in semiconductor manufacturing is preferable.

In the present invention, in particular, a base material having a polar group on the surface thereof may be preferably used. By using the base material having a polar group on the surface thereof, there is a tendency for further improvements in adhesiveness to a resin composition for underlayer film formation. Examples of the polar group include a hydroxyl group, a carboxyl group, and a silanol group. A silicon base material and a quartz base material are particularly preferable.

The shape of the base material is also not particularly limited, and may be plate-like or roll-like. The base material is also selectable from those of light transmissive and non-light transmissive types, depending on the combination with a mold, or the like.

On the surface of the underlayer film, a pattern may be formed by the above-mentioned photocurable composition. The pattern may be used, for example, as an etching resist. The base material in this case is exemplified by a base material (silicon wafer) having a thin film of Spin On Carbon (SOC), Spin On Glass (SOG), SiO₂, or silicon nitride formed thereon. A plurality of etching onto a base material may be carried out at the same time.

The laminate having a pattern formed thereon may be used as a permanent film in devices or structures, in an intact form, or in a form obtained after removing any residual film in recessed portions or removing the underlayer film. Such a laminate is less causative of film peeling and is therefore useful, even when environmental changes or stress are applied thereto.

<Pattern Forming Method>

Next, the pattern forming method according to the present invention will be described.

The pattern forming method according to the present invention includes a step of applying the resin composition for underlayer film formation according to the present invention onto the surface of a base material in the form of layer (step 1); a step of heating the applied resin composition for underlayer film formation to form an underlayer film (step 2); a step of applying a photocurable composition (photocurable composition for imprints) onto the surface of the underlayer film or a mold having a pattern in the form of layer (step 3); a step of sandwiching the photocurable composition between the mold and the base material (step 4); a step of curing the photocurable composition by photoirradiation, in a state where the photocurable composition is sandwiched between the mold and the base material (step 5); and a step of peeling the mold (step 6).

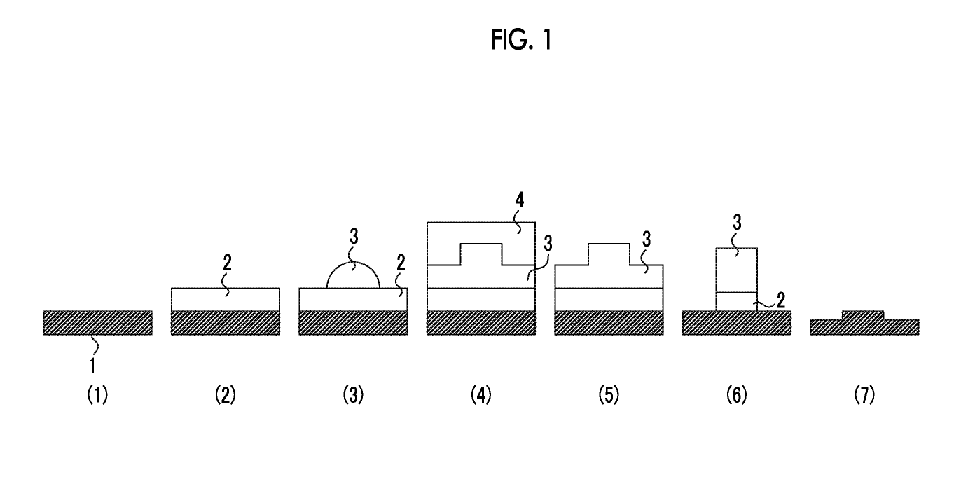

FIG. 1 is a schematic view illustrating an example of a production process when a photocurable composition is used for etching of a base material, in which reference numeral 1 stands for a base material, 2 stands for an underlayer film, 3 stands for an imprint layer, and 4 stands for a mold. In FIG. 1, a resin composition for underlayer film formation is applied onto the surface of the base material 1 (2), the photocurable composition is applied onto the surface (3), and the mold is applied onto the surface thereof (4). After photoirradiation is carried out, the mold is peeled (5). Etching is carried out according to a pattern (an imprint layer 3) formed by the photocurable composition (6), and the imprint layer 3 and the underlayer film 2 are peeled to thereby form a base material with a desired pattern formed thereon (7). The adhesiveness between the base material 1 and the imprint layer 3 is important, since a poor level of adhesiveness between the base material 1 and the imprint layer 3 results in failing to exactly transfer the pattern of the mold 4.

Hereinafter, details of the pattern forming method according to the present invention will be described.

<<Step 1>>

First, a resin composition for underlayer film formation is applied onto the surface of a base material in the form of layer. As the base material, the base material described in the foregoing laminate can be mentioned. The method of applying a resin composition for underlayer film formation is preferably a coating method. Examples of the coating method include dip coating, air knife coating, curtain coating, wire bar coating, gravure coating, extrusion coating, spin coating, slit scan coating, and inkjet coating. Spin coating is preferable from the viewpoint of film thickness uniformity.

The coating amount of the resin composition for underlayer film formation is, for example, preferably 1 to 10 nm, and more preferably 3 to 8 nm in terms of film thickness after curing.

<<Step 2>>

Next, the resin composition for underlayer film formation applied onto the base material surface is heated to form an underlayer film.

The resin composition for underlayer film formation applied onto the base material surface is preferably dried to remove a solvent. The drying temperature may be appropriately adjusted according to the boiling point of the solvent contained in the resin composition for underlayer film formation. For example, a preferred drying temperature is 70° C. to 130° C.

After drying if necessary, the resin composition for underlayer film formation is heated and cured to form an underlayer film. Regarding the heating conditions, it is preferred that the heating temperature (baking temperature) is 120° C. to 250° C., and the heating time is 30 seconds to 10 minutes.

The removal of a solvent and the curing by heating may be carried out at the same time.

In the present invention, it is preferred that the resin composition for underlayer film formation is applied onto the base material surface, followed by heating to cure at least a portion of the resin composition for underlayer film formation, and then a photocurable composition is applied onto the surface of the underlayer film. When such means is adopted, the resin composition for underlayer film formation is also completely cured at the time of photocuring the photocurable composition, and the adhesiveness tends to be further improved.

<<Step 3>>

Next, a photocurable composition is applied onto the surface of the underlayer film or a mold having a pattern in the form of layer (the photocurable composition applied in the form of layer is also referred to as a patterning layer). The method of applying the photocurable composition may employ the same method as the above-mentioned application method of a resin composition for underlayer film formation.

<<Step 4>>

Next, the patterning layer (photocurable composition) is sandwiched between the mold and the base material. As a result, a fine pattern previously formed on the surface of the mold can be transferred onto the patterning layer.

The mold is preferably a mold having a pattern to be transferred. The pattern on the mold may be formed with a desired level of processing accuracy, for example, by photolithography, electron beam lithography, or the like.

The material of the mold is not particularly limited and may be any one having a predetermined strength and durability. Specific examples of the light transmissive mold material include glass, quartz, a light-transparent resin such as an acrylic resin or a polycarbonate resin, a transparent evaporated metal film, a flexible film of polydimethylsiloxane or the like, a photocured film, and a metal film. A non-light transmissive mold can also be used in the case where a light transmissive base material is used. The material of the non-light transmissive mold is not particularly limited and may be any one having a predetermined strength. Specific examples of the non-light transmissive mold material include, but are not particularly limited to, a ceramic material, an evaporated film, a magnetic film, a reflective film, a metal such as Ni, Cu, Cr, or Fe, SiC, silicon, silicon nitride, polysilicon, silicon oxide, and amorphous silicon. The shape of the mold is also not particularly limited, and may be any of a plate-like mold or a roll-like mold. The roll-like mold is applied especially when continuous transfer in patterning is desired.

The mold for use in the present invention may be subjected to a surface release treatment for the purpose of enhancing the peelability of the photocurable composition from the mold. The mold of such a type includes those surface-treated with a silicon-based or fluorine-based silane coupling agent, for which, for example, commercially available mold release agents such as OPTOOL DSX manufactured by Daikin Industries, Ltd., and Novec EGC-1720 manufactured by Sumitomo 3M Ltd. may be suitably used.

In the case of sandwiching the patterning layer between the mold and the base material, helium may be introduced between the mold and the patterning layer surface. By using such a method, the permeation of gases through the mold is promoted, so it is possible to facilitate the elimination of residual air bubbles. Further, it is possible to suppress radical polymerization inhibition in the exposure by reducing the dissolved oxygen in the patterning layer. Alternatively, a condensable gas instead of helium may be introduced between the mold and the patterning layer. By using such a method, it is possible to further accelerate the disappearance of residual air bubbles by utilizing the fact that the introduced condensable gas is condensed to result in a decrease in the volume thereof. The condensable gas refers to a gas which is condensed by temperature and pressure, and for example, trichlorofluoromethane, 1,1,1,3,3-pentafluoropropane, or the like may be used. The condensable gas may be referred to, for example, the description of paragraph “0023” of JP2004-103817A and paragraph “0003” of JP2013-254783A, the contents of which are incorporated herein by reference in their entirety.

<<Step 5>>

Then, the patterning layer (photocurable composition) is cured by photoirradiation in a state where the patterning layer is sandwiched between the mold and the base material. The dose of photoirradiation may be sufficiently larger than the dose necessary for curing of the photocurable composition. The dose necessary for curing may be suitably determined depending on the degree of consumption of the unsaturated bonds in the photocurable composition and on the tackiness of the cured film as previously determined.

With respect to the temperature at the time of photoirradiation, the photoirradiation is usually carried out at room temperature, but the photoirradiation may alternatively be carried out while heating the base material for the purpose of enhancing the reactivity. Photoirradiation can also be carried out in vacuo, since a vacuum conditioning as a preliminary stage of the photoirradiation is effective for preventing entrainment of air bubbles, for suppressing the reactivity from being reduced due to incorporation of oxygen, and for improving the adhesiveness between the mold and the photocurable composition. In the pattern forming method according to the present invention, the degree of vacuum at the time of photoirradiation is preferably in the range of 10⁻¹ Pa to normal pressure.

Upon exposure, the exposure illuminance is preferably set to be within the range of 1 to 50 mW/cm². When the light intensity is 1 mW/cm² or more, then the producibility may increase since the exposure time may be reduced; and when the light intensity is 50 mW/cm² or less, then it is preferable since there is a tendency that the properties of the permanent film formed may be prevented from being degraded owing to side reaction. The exposure dose is preferably set to be within the range of 5 to 1,000 mJ/cm². When the exposure dose is within such a range, curability of the photocurable composition is favorable. Further, when the exposure is carried out, the oxygen concentration in the atmosphere may be controlled to be less than 100 mg/L by introducing an inert gas such as nitrogen or argon into the system for preventing the radical polymerization from being inhibited by oxygen.

In the pattern forming method of the present invention, after the patterning layer (photocurable composition) is cured through photoirradiation, if desired, the cured pattern may be further cured under heat given thereto. The heating temperature is, for example, preferably 150° C. to 280° C., and more preferably 200° C. to 250° C. The heating time is, for example, preferably 5 to 60 minutes, and more preferably 15 to 45 minutes.

<<Step 6>>

A pattern according to the shape of a mold can be formed by curing the photocurable composition as described above, and then peeling the mold.

Specific examples of the pattern forming method include the methods described in paragraphs “0125” to “0136” of JP2012-169462A, the contents of which are incorporated herein by reference in its entirety.

Further, the pattern forming method according to the present invention can be applied to a pattern reversal method. The pattern reversal method is carried out as follows. Specifically, first, a resist pattern is formed on a base material such as a carbon film (SOC) by the pattern forming method according to the present invention. Subsequently, the resist pattern is coated with such a Si-containing film (SOG), an upper portion of the Si-containing film is subjected to etching back such that the resist pattern is exposed, and then the exposed resist pattern is removed by oxygen plasma or the like, whereby it is possible to form a reversal pattern of the Si-containing film. Further, using the reversal pattern of the Si-containing film as an etching mask, the base material thereunder is etched whereby the reversal pattern is transferred onto the base material. Finally, using the base material having the reversal pattern transferred thereon as an etching mask, the base material is etching-processed. Examples of such a method can be referred to JP1993-267253A (JP-H05-267253A), JP2002-110510A, and paragraphs “0016” to “0030” of JP2006-521702A, the contents of which are incorporated herein by reference in their entirety.

<Pattern>

As described above, the pattern formed by the pattern forming method according to the present invention can be used as a permanent film used for a liquid crystal display (LCD) or the like, or as an etching resist for semiconductor processing. Further, by using the pattern according to the present invention to form a grid pattern on a glass substrate of a liquid crystal display device, it is possible to produce a polarizing plate exhibiting little reflection and absorption and having a large screen size (for example, 55 inches, 60 inches or more) at a low cost. For example, the polarizing plate described in JP2015-132825A or WO2011/132649A can be produced. It should be noted that 1 inch is 25.4 mm.

For example, the pattern formed by the pattern forming method according to the present invention can be preferably used for the production of a recording medium such as a semiconductor integrated circuit, a micro electro mechanical system (MEMS), an optical disc, or a magnetic disc, a light receiving element such as a solid image pickup element, an optical device of a light emitting element such as a LED, an organic EL, or a liquid crystal display device (LCD), an optical component such as a diffraction grating, a relief hologram, an optical waveguide, an optical filter, or a microlens array, a thin film transistor, an organic transistor, a color filter, an antireflection film, a polarizing element such as a polarizing plate, an optical film, a member for flat panel displays such as a pillar material, a nanobio device, an immunoassay chip, a deoxyribonucleic acid (DNA) separation chip, a microreactor, a photonic liquid crystal, a guide pattern for directed self-assembly (DSA) using self-organization of a block copolymer, or the like.

<Imprint Forming Kit>

Next, an imprint forming kit of the present invention will be described.

The imprint forming kit of the present invention includes the above-mentioned resin composition for underlayer film formation and a photocurable composition.

The composition and preferred range of each of the resin composition for underlayer film formation and the photocurable composition are the same as those described above.

The imprint forming kit of the present invention can be preferably used in the above-mentioned pattern forming method.

<Method for Producing Device>

The method for producing a device according to the present invention includes the above-mentioned pattern forming method.

That is, a device can be produced by forming a pattern using the above-mentioned method and then applying the method used in the production of various devices.

The pattern may be included as a permanent film in the device. Also, using the pattern as an etching mask, the base material may also be subjected to an etching process. For example, the base material is subjected to dry etching using the pattern as an etching mask to thereby selectively remove the upper layer portion of the base material. The base material is repeatedly subjected to such processing, whereby it is possible to manufacture a device. The device may be, for example, a semiconductor device such as a large-scale integrated circuit (LSI).

### EXAMPLES

Hereinafter, this invention will be described in more detail with reference to Examples. Materials, amounts to be used, ratios, details of processes, and procedures of processes described in the following Examples may be modified suitably, without departing from the spirit of this invention. Therefore, the scope of this invention is not limited thereto. The expressions “parts” and “%” are based on mass unless otherwise specified.

<Measurement of Weight-Average Molecular Weight>

The weight-average molecular weight was measured by the following method.

Column: column in which 3 columns of TSKgel Super Multipore HZ-H (manufactured by Tosoh Corporation, 4.6 mm (inner diameter)×15 cm) are connected in series

Development solvent: tetrahydrofuran

Column temperature: 40° C.

Sample concentration: 0.35 mass %

Flow rate: 0.35 mL/min

Sample injection volume: 10 μL

Device: HLC-8020 GPC manufactured by Tosoh Corporation

Detector: refractive index (RI) detector

Calibration curve base resin: polystyrene

<Synthesis of Resin A-1>

100 g of propylene glycol monomethyl ether acetate (PGMEA) was placed in a flask which was then warmed to 90° C. under a nitrogen atmosphere. To the solution, a mixture of 34.5 g (0.40 mol) of methacrylic acid (MAA) (manufactured by Wako Pure Chemical Industries, Ltd.), 2.8 g (12 mmol) of dimethyl 2,2′-azobis(2-methylpropionate) (V-601); (manufactured by Wako Pure Chemical Industries, Ltd.), and 50 g of PGMEA was added dropwise over 2 hours. After completion of the dropwise addition, the mixture was further stirred at 90° C. for 4 hours to obtain an MAA polymer.

To the solution of the MAA polymer, 85.4 g (0.40 mol) of glycidyl methacrylate (GMA) (manufactured by Wako Pure Chemical Industries, Ltd.), 2.1 g of tetraethylammonium bromide (TEAB) (manufactured by Wako Pure Chemical Industries, Ltd.), and 50 mg of 4-hydroxy-2,2,6,6-tetramethylpiperidine-1-oxyl (4-HO-TEMPO) (manufactured by Wako Pure Chemical Industries, Ltd.) were added, followed by reaction at 90° C. for 8 hours. It was confirmed from the H-NMR (nuclear magnetic resonance) that GMA disappeared in the reaction, and the reaction was then terminated. After completion of the reaction, 200 mL of ethyl acetate was added, and the mixture was separately extracted with sodium bicarbonate water and then dilute aqueous hydrochloric acid to remove excess acrylic acid and TEAB of the catalyst, finally washed with pure water, and then dissolved in PGMEA to obtain a PGMEA solution of Resin A-1. The obtained A-1 had a weight-average molecular weight (Mw, in terms of polystyrene) of 14,000 as measured by gel permeation chromatography (GPC), and a dispersity (Mw/Mn) of 2.2.

<Synthesis of Resin A-2>

100 g of PGMEA was placed in a flask which was then warmed to 90° C. under a nitrogen atmosphere. To the solution, a mixture of 20.7 g (0.24 mol) of methacrylic acid (MAA) (manufactured by Wako Pure Chemical Industries, Ltd.), 20.8 g (0.16 mol) of hydroxyethyl methacrylate (HEMA) (manufactured by Wako Pure Chemical Industries, Ltd.), 2.8 g (12 mmol) of V-601, and 50 g of PGMEA was added dropwise over 2 hours. After completion of the dropwise addition, the mixture was further stirred at 90° C. for 4 hours to obtain an MAA/HEMA copolymer.

To the solution of the MAA/HEMA copolymer, 51.3 g (0.24 mol) of glycidyl methacrylate (GMA) (manufactured by Wako Pure Chemical Industries, Ltd.), 2.1 g of tetraethylammonium bromide (TEAB) (manufactured by Wako Pure Chemical Industries, Ltd.), and 50 mg of 4-hydroxy-2,2,6,6-tetramethylpiperidine-1-oxyl (4-HO-TEMPO) (manufactured by Wako Pure Chemical Industries, Ltd.) were added, followed by reaction at 90° C. for 8 hours. It was confirmed from the H-NMR that GMA disappeared in the reaction, and the reaction was then terminated. After completion of the reaction, 200 mL of ethyl acetate was added, and the mixture was separately extracted with sodium bicarbonate water and then dilute aqueous hydrochloric acid to remove excess acrylic acid and TEAB of the catalyst, finally washed with pure water, and then dissolved in PGMEA to obtain a PGMEA solution of Resin A-2. The obtained A-2 had Mw of 18,000 and a dispersity (Mw/Mn) of 2.2.

TABLE 1

| | HEMA | GMA-AA | Mw | Dispersity |
|---|---|---|---|---|
| A-1 | | 100 | 14000 | 2.2 |
| A-2 | 40 | 60 | 18000 | 2.2 |

The structures of the resins used in the present invention are shown below. x and z are the molar ratio of each repeating unit, which can be calculated from the above table.

TABLE 2

| | Resin (A) |
|---|---|
| A-1 | 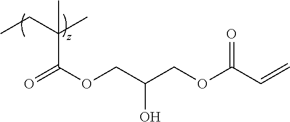 |
| A-2 | 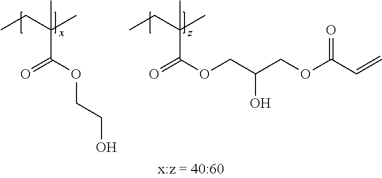 |

<Synthesis of Resin A-3>

Propylene glycol monomethyl ether acetate (PGMEA) (28.5 g) was placed in a flask which was then warmed to 90° C. under a nitrogen atmosphere. To the solution, a mixture of glycidyl methacrylate (GMA, manufactured by Wako Pure Chemical Industries, Ltd.) (14.2 g), 1-ethylcyclopentylmethacrylate (EtCPMA, manufactured by Osaka Organic Chemical Industry Ltd.) (18.2 g), dimethyl 2,2′-azobis(2-methylpropionate) (V-601, manufactured by Wako Pure Chemical Industries, Ltd.) (1.1 g) and PGMEA (28.5 g) was added dropwise over 4 hours. After completion of the dropwise addition, the reaction mixture was further stirred at 90° C. for 4 hours to obtain a PGMEA solution of the GMA polymer.

To the solution of the GMA polymer, acrylic acid (AA, manufactured by Wako Pure Chemical Industries, Ltd.) (15.0 g), tetrabutylammonium bromide (TBAB, manufactured by Wako Pure Chemical Industries, Ltd.) (2.0 g), and 4-hydroxy-2,2,6,6-tetramethylpiperidine-1-oxyl free radicals (4-HO-TEMPO, manufactured by Wako Pure Chemical Industries, Ltd.) (50 mg) were added, followed by reaction at 90° C. for 10 hours. After the completion of the reaction, 200 mL of ethyl acetate was added thereto, followed by a reparatory extraction with sodium bicarbonate water and then dilute aqueous hydrochloric acid to remove excess acrylic acid and TBAB of the catalyst. Finally, the extract was washed with pure water. This was followed by concentration under reduced pressure to distill off ethyl acetate. The obtained Resin A-3 had a weight-average molecular weight of 15,100 and a dispersity (weight-average molecular weight/number-average molecular weight) of 1.8.

<Synthesis of Resin A-4>

PGMEA (100 g) was placed in a flask which was then warmed to 90° C. under a nitrogen atmosphere. To the solution, a mixture of glycidyl methacrylate (GMA, manufactured by Wako Pure Chemical Industries, Ltd.) (56.9 g), dimethyl 2,2′-azobis(2-methylpropionate) (V-601, manufactured by Wako Pure Chemical Industries, Ltd.) (3.7 g), and PGMEA (50 g) was added dropwise over 2 hours. After completion of the dropwise addition, further stirring was carried out at 90° C. for 4 hours to obtain a PGMEA solution of the GMA polymer.

To the solution of the GMA polymer, AA (14.4 g), TBAB (2.1 g), and 4-HO-TEMPO (50 mg) were added, followed by reaction at 90° C. for 10 hours. After completion of the reaction, 200 mL of ethyl acetate was added, and the mixture was separately extracted with sodium bicarbonate water and then dilute aqueous hydrochloric acid to remove excess acrylic acid and TBAB of the catalyst, and finally washed with pure water. The obtained Resin A-4 had a weight-average molecular weight of 14,000 and a dispersivity of 2.0. The molar ratio of acryloyloxy group:glycidyl group calculated from the area ratio of H-NMR was 50:50.

The structures of resins are shown below. x and y represent the molar ratio of each repeating unit. In the following formulae, Me represents a methyl group.

TABLE 3

| | | | weight- |
|---|---|---|---|
| | | | average |
| | | | molecular |
| | Resin | x:y | weight |
| A-3 | 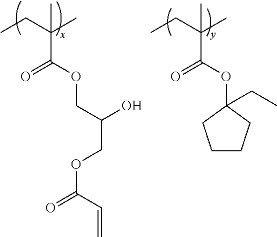 | 50:50 | 15100 |

TABLE 4

| | | | weight- |
|---|---|---|---|
| | | | average |
| | | | molecular |
| | Resin | x:y | weight |
| A-4 | 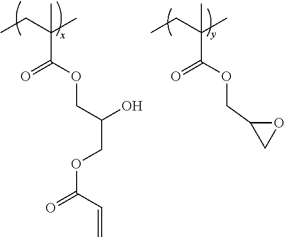 | 50:50 | 12500 |

A-5 PVEEA manufactured by Nippon Shokubai Co., Ltd.

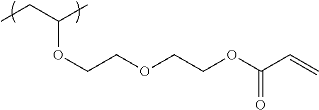

Weight-average molecular weight: 21,000 Dispersity: 2.2

<Preparation of Resin Composition for Underlayer Film Formation>

The resin composition components were dissolved at the solid content ratio (mass ratio) shown in Tables below and to a total solid content of 0.3 mass % in a solvent. The solution was filtered through a polytetrafluoroethylene (PTFE) filter having a pore size of 0.1 μm to obtain a resin composition for underlayer film formation.

TABLE 5

| | | | Nucleophilic | | | | | |
|---|---|---|---|---|---|---|---|---|
| | Resin | | catalyst | | Surfactant | | | |
| | | Part by | | Part by | | Part by | Water | |
| | Type | mass | Type | mass | Type | mass | (mass %) | Solvent |
| Example 1-1 | A-1 | 100 | BMIM | 0.05 | — | — | 0.03 | PGMEA |
| Example 1-2 | A-2 | 100 | BMIM | 0.05 | — | — | 0.03 | PGMEA |
| Example 1-3 | A-1 | 100 | BMIM | 0.3 | — | — | 0.1 | PGMEA |
| Example 1-4 | A-1 | 100 | BMIM | 0.02 | — | — | 0.03 | PGMEA |
| Example 1-5 | A-2 | 100 | BMIM | 1 | — | — | 0.1 | PGMEA |
| Example 1-6 | A-1 | 100 | BMIM | 2.5 | — | — | 0.1 | PGMEA |
| Example 1-7 | A-1 | 100 | BMIM | 0.05 | W-1 | 1 | 0.03 | PGMEA |
| Example 1-8 | A-1 | 100 | BMIM | 0.05 | W-2 | 1 | 0.03 | PGMEA |
| Example 1-9 | A-2 | 100 | BMIM | 0.2 | W-1 | 3 | 0.03 | PGMEA |
| Example 1-10 | A-1 | 100 | BMIM | 0.1 | W-3 | 3 | 0.03 | PGMEA |
| Example 1-11 | A-2 | 100 | BMIM | 0.1 | W-4 | 3 | 0.03 | PGMEA |
| Example 1-12 | A-3 | 100 | BMIM | 0.3 | — | — | 0.03 | PGMEA |
| Example 1-13 | A-4 | 100 | BMIM | 0.3 | — | — | 0.03 | PGMEA |
| Example 1-14 | A-3 | 100 | BMIM | 0.5 | W-1 | 3 | 0.03 | PGMEA |
| Example 1-15 | A-4 | 100 | BMIM | 0.5 | W-2 | 3 | 0.03 | PGMEA |
| Example 1-16 | A-3 | 100 | BMIM | 1 | W-3 | 3 | 0.03 | PGMEA |
| Example 1-17 | A-4 | 100 | BMIM | 1 | W-4 | 3 | 0.03 | PGMEA |
| Example 1-18 | A-1 | 100 | DMAP | 0.05 | — | — | 0.03 | PGMEA |
| Example 1-19 | A-2 | 100 | DMAP | 0.05 | — | — | 0.03 | PGMEA |
| Example 1-20 | A-3 | 100 | Ph3P | 0.05 | — | — | 0.03 | PGMEA |
| Example 1-21 | A-1 | 100 | DMAP | 0.3 | W-1 | 3 | 0.03 | PGMEA |
| Example 1-22 | A-2 | 100 | DMAP | 0.3 | W-2 | 3 | 0.03 | PGMEA |
| Example 1-23 | A-3 | 100 | Ph3P | 0.3 | W-3 | 3 | 0.03 | PGMEA |
| Example 1-24 | A-5 | 100 | DMAP | 0.05 | — | — | 0.03 | PGMEA |
| Example 1-25 | A-5 | 100 | DMAP | 0.3 | W-2 | 3 | 0.03 | PGMEA |
| Example 1-26 | A-5 | 100 | TEAB | 0.05 | — | — | 0.03 | PGMEA |
| Example 1-27 | A-5 | 100 | TEAB | 0.3 | W-2 | 3 | 0.03 | PGMEA |
| Example 1-28 | A-5 | 100 | BTAB | 0.05 | — | — | 0.03 | PGMEA |
| Example 1-29 | A-5 | 100 | BTAB | 0.3 | W-2 | 3 | 0.03 | PGMEA |
| Example 1-30 | A-2/A-3 | 50/50 | DMAP | 0.05 | — | — | 0.03 | PGMEA |
| Example 1-31 | A-2/A-4 | 70/30 | Ph3P | 0.05 | — | — | 0.03 | PGMEA |
| Example 1-32 | A-2 | 100 | DAMP/Ph3P | 0.05 | — | — | 0.03 | PGMEA |
| Example 1-33 | A-1 | 100 | BMIM | 0.05 | — | — | 0.03 | 2-Heptanone |
| Example 1-34 | A-2 | 100 | BMIM | 0.05 | — | — | 0.03 | Ethoxyethyl |
| | | | | | | | | propionate |
| Comparative | A-1 | 100 | BMIM | 5 | — | — | 0.03 | PGMEA |
| Example 1-1 | | | | | | | | |
| Comparative | A-2 | 100 | BMIM | 5 | — | — | 0.03 | PGMEA |
| Example 1-2 | | | | | | | | |
| Comparative | A-3 | 100 | BMIM | 5 | — | — | 0.6 | PGMEA |
| Example 1-3 | | | | | | | | |
| Comparative | A-4 | 100 | BMIM | 5 | — | — | 0.9 | PGMEA |
| Example 1-4 | | | | | | | | |
| Comparative | A-1 | 100 | BMIM | <0.001 | — | — | 0.01 | PGMEA |
| Example 1-5 | | | | | | | | |
| Comparative | A-2 | 100 | BMIM | <0.001 | — | — | 0.01 | PGMEA |
| Example 1-6 | | | | | | | | |
| Comparative | A-3 | 100 | BMIM | <0.001 | — | — | 0.6 | PGMEA |
| Example 1-7 | | | | | | | | |
| Comparative | A-4 | 100 | BMIM | <0.001 | — | — | 0.9 | PGMEA |
| Example 1-8 | | | | | | | | |

TABLE 6

| | | | Nucleophilic | | Crosslinking | | | | | | | |
|---|---|---|---|---|---|---|---|---|---|---|---|---|
| | Resin | | catalyst | | agent | | Catalyst | | Surfactant | | | |
| | | Part by | | Part by | | Part by | | Part by | | Part by | Water | |
| | Type | mass | Type | mass | Type | mass | Type | mass | Type | mass | (mass %) | Solvent |
| Example 2-1 | A4 | 80 | Ph3P | 0.1 | B1 | 20 | C1 | 3 | — | — | 0.02 | PGMEA |
| Example 2-2 | A5 | 100 | Ph3P | 0.1 | | | | | — | — | 0.05 | PGMEA |
| Example 2-3 | A6 | 75 | Ph3P | 0.4 | B1 | 25 | C1 | 3 | W-1 | 1 | 0.02 | PGMEA |
| Example 2-4 | A7 | 100 | Ph3P | 0.4 | | | | | W-2 | 3 | 0.07 | PGMEA |
| Example 2-5 | A6 | 90 | Ph3P | 0.04 | B1 | 10 | C1 | 0.8 | W-1 | 1 | 0.03 | PGMEA |
| Example 2-6 | A7 | 100 | Ph3P | 0.04 | | | | | W-2 | 3 | 0.06 | PGMEA |
| Example 2-7 | A6 | 80 | Ph3P | 3 | B1 | 20 | C1 | 3 | W-3 | 1 | 0.06 | PGMEA |
| Example 2-8 | A7 | 100 | Ph3P | 3 | | | | | W-4 | 3 | 0.09 | PGMEA |
| Example 2-9 | A4 | 80 | ETPP | 0.4 | B1 | 20 | C1 | 3 | — | — | 0.09 | PGMEA/ |
| | | | | | | | | | | | | PGME |
| Example 2-10 | A5 | 100 | ETPP | 0.4 | | | | | W-4 | 3 | 0.09 | PGMEA/ |
| | | | | | | | | | | | | PGME |
| Comparative | A7 | 80 | Ph3P | 5 | B1 | 20 | C1 | 5 | — | — | 0.01 | PGMEA |
| Example 2-1 | | | | | | | | | | | | |
| Comparative | A7 | 100 | Ph3P | 0.001 | | | | | — | — | 0.5 | PGMEA |
| Example 2-2 | | | | | | | | | | | | |

(Resin)

A-1 to A-5: Resins A-1 to A-5

A4: PGMEA (100 g) was placed in a flask, and 40 g of a commercially available resin NK OLIGO EA 7120 (manufactured by Shin-Nakamura Chemical Co., Ltd.) was added thereto, followed by stirring for 2 hours to completely dissolve the resin. After dissolution, 200 mL of ethyl acetate was added, and the mixture was separately extracted with sodium bicarbonate water and then dilute aqueous hydrochloric acid to remove excess raw material components and catalyst components, and finally washed with pure water to obtain Resin A4.

A5: Resin A5 was obtained in the same manner as A4, except that NK OLIGO EA 7140 (manufactured by Shin-Nakamura Chemical Co., Ltd.) was used as a commercially available resin in the preparation of A4.

A6: Resin A6 was obtained in the same manner as A4, except that NK OLIGO EA 7420 (manufactured by Shin-Nakamura Chemical Co., Ltd.) was used as a commercially available resin in the preparation of A4.

A7: Resin A7 was obtained in the same manner as A4, except that NK OLIGO EA 7440 (manufactured by Shin-Nakamura Chemical Co., Ltd.) was used as a commercially available resin in the preparation of A4.

(Crosslinking Agent)

B1: CYMEL 303 ULF (manufactured by Cytec Industries Co., Ltd.)

(Catalyst)

C1: CYCAT 4040 (manufactured by Cytec Industries Co., Ltd.)

(Nucleophilic catalyst)

TEAB: Tetraethylammonium bromide (Wako Pure Chemical Industries, Ltd.)

Ph3P: Triphenylphosphine (Wako Pure Chemical Industries, Ltd.)

BMIM: 1-Benzyl-2-methylimidazole (Tokyo Chemical Industry Co., Ltd.)

DMAP: Dimethylaminopyridine (Tokyo Chemical Industry Co., Ltd.)

BTAB: Benzyltriethylammonium bromide (Nacalai Tesque)

ETPP: Ethyltriphenylphosphonium bromide (Wako Pure Chemical Industries, Ltd.)

(Surfactant)

<Nonionic Surfactant>

W-1: Capstone FS-3100 (manufactured by E.I. du Pont de Nemours and Company Co., Ltd.)

W-2: Polyfox PF 6520 (manufactured by OMNOVA Solutions Inc.)

W-3: FL-5 (manufactured by Shin-Etsu Chemical Co., Ltd.)

W-4: Newcol 1008 (manufactured by Nippon Nyukazai Co., Ltd.)

(Solvent)

PGMEA: Propylene glycol monomethyl ether acetate

PGME: Propylene glycol monomethyl ether

<Preparation of Photocurable Composition V1 for Imprints>

A polymerizable compound, a photopolymerization initiator, and additives shown in the following table were mixed. Further, 4-hydroxy-2,2,6,6-tetramethylpiperidine-1-oxyl free radicals (manufactured by Tokyo Chemical Industry Co., Ltd.) as a polymerization inhibitor were added to 200 ppm (0.02 mass %) relative to the monomer. This was filtered through a PTFE filter having a pore size of 0.1 μm to prepare a photocurable composition V1 for imprints. In the table, individual components are given in terms of mass ratio.

TABLE 7

| | | Mass |
|---|---|---|
| | Available from | ratio |
| M-1 | VISCOAT #192 (manufactured by Osaka | 48 |
| | Organic Chemical Industry, Ltd.) | |
| M-2 | Synthesized from α,α′-dichloro-m-xylene | 48 |
| | and acrylic acid | |
| M-3 | R-1620 (manufactured by Daikin Industries, | 2 |
| | Ltd.) | |
| Photopolymerization | Irgacure 907 (manufactured by BASF | 2 |
| initiator | Corporation) | |

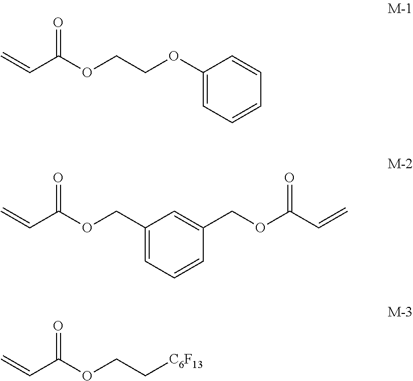

<Formation of Underlayer Film>

A resin composition for underlayer film formation was spin-coated on the surface of a silicon wafer, and heated on a hot plate at 100° C. for 1 minute to dry a solvent. Further, baking (heating) was carried out on a hot plate at 180° C. for 5 minutes, thereby forming an underlayer film on the surface of the silicon wafer. The film thickness of the underlayer film after curing was 5 nm.

<Evaluation of Surface State of Underlayer Film>

The following evaluation of the surface roughness Ra and the coating particles was used as an index of the coating surface state evaluation.

<Evaluation of Surface Roughness Ra of Underlayer Film>

Using an atomic force microscope (AFM, Dimension Icon manufactured by Bruker AXS Ltd.), a 10 μm square of the underlayer film obtained above was measured at a 1024×1024 pitch for surface roughness data, and the arithmetic average surface roughness (Ra) was calculated.

<Evaluation of Coating Particles of Underlayer Film>

The underlayer film obtained above was subjected to a coating defect inspection using a Surfscan SP1 (manufactured by KLA Tencor Corporation) and the number of defects detected as coating defects of 0.2 μm or more was measured at n=5. The average value of the measured values was evaluated according to the following classification.

A: 50 or less

B: more than 50 and 300 or less

C: more than 300 and 500 or less

D: more than 500

<Evaluation of Adhesiveness>

The resin composition for underlayer film formation was spin-coated on the surface of a 700-μm-thick silicon wafer having a thermal oxide film with a thickness of 50 nm and the surface of a quartz wafer having a thickness of 525 μm, respectively, and heated on a hot plate at 100° C. for 1 minute to thereby dry up the solvent. The wafer was further heated on a hot plate at 220° C. for 5 minutes to cure the composition for underlayer film formation, thereby forming an underlayer film. The film thickness of the underlayer film after curing was 5 nm.

On the surface of the underlayer film formed on the silicon wafer, the photocurable composition V1 for imprints conditioned at 25° C. was ejected and coated in a circle having a radius of 40 mm using an inkjet printer “DMP-2831” manufactured by Fujifilm Dimatix, Inc., at a liquid droplet volume per nozzle of 1 pl, so as to align the droplets according to an approximately 100 μm-pitch square array on the underlayer film. From above, the quartz wafer was placed so as to bring the underlayer film side into contact with the patterning layer (curable composition layer for imprints), followed by exposure to light from the quartz wafer side using a high pressure mercury lamp at an irradiation dose of 300 mJ/cm². After the exposure, the quartz wafer was separated, and the releasing force at that time was measured.

This releasing force corresponds to the adhesive force F (unit: N) between the silicon wafer and the curable composition for imprints. The releasing force was measured according to the method described in the Comparative Examples in paragraphs “0102” to “0107” of JP2011-206977A. That is, the measurement was carried out according to peeling steps 1 to 6 and 16 to 18 in FIG. 5 of this publication.

S: F≧45

A: 45>F≧40

B: 40>F≧30

C: 30>F≧20

D: 20>F

<Evaluation 1 of Pattern Defect>

Over the surface of the underlayer film formed on the above-mentioned silicon wafer, the photocurable composition V1 for imprints conditioned at 25° C. was ejected and coated using an inkjet printer “DMP-2831” manufactured by Fujifilm Dimatix, Inc., at a liquid droplet volume per nozzle of 6 pl, so as to align the droplets according to an approximately 280 μm-pitch square array on the underlayer film, thereby forming a patterning layer. A quartz mold (rectangular line/space pattern (1/1), line width=60 nm, groove depth=60 nm, and line edge roughness=3.5 nm) was then pressed against the patterning layer, so as to fill the patterning layer (photocurable composition for imprints) into the mold. After 10 seconds from the contact between the mold and the photocurable composition for imprints on the entire surface of the pattern region, exposure was carried out using a high pressure mercury lamp from the mold side at an irradiation dose of 300 mJ/cm², and thereafter the mold was peeled, whereby the pattern was transferred to the patterning layer.

The pattern, thus, transferred to the patterning layer was observed under an optical microscope (L200 D manufactured by Nikon Corporation), the number of bright points was determined in a dark field, and the number of defects per 1 cm² was calculated.

A: 300 or less

B: more than 300 and 500 or less

C: more than 500 and 700 or less

D: more than 700 and 1000 or less

E: more than 1000

<Evaluation 2 of Pattern Defect>

The solution of 20 parts by mass of tetramethyl orthosilicate (TMOS), 80 parts by mass of methyltrimethoxysilane (MTMS), and 0.5 parts by mass of maleic acid mixed and dissolved in 1-propoxy-2-propanol was applied onto a silicon wafer to form a film having a thickness of 40 nm and calcined at 200° C. for 60 seconds to form a Spin On Glass (SOG) film on the surface of the silicon wafer.

The resin composition for underlayer film formation was spin-coated on the surface of the SOG film formed on the silicon wafer, and heated on a hot plate at 100° C. for 1 minute to thereby dry up the solvent. The resin composition for underlayer film formation was further baked (heated) on a hot plate at 180° C. for 5 minutes to thereby form an underlayer film on the surface of the silicon wafer having an SOG film. The film thickness of the underlayer film after curing was 5 nm.

On the surface of the underlayer film, the photocurable composition for imprints conditioned at 25° C. was ejected and coated using an inkjet printer “DMP-2831” manufactured by Fujifilm Dimatix, Inc., at a liquid droplet volume per nozzle of 6 pl, so as to align the droplets according to an approximately 280 μm-pitch square array on the underlayer film, thereby forming a patterning layer. A quartz mold (rectangular line/space pattern (1/1), line width=50 nm, groove depth=90 nm, and line edge roughness=3.5 nm) was then pressed against the patterning layer, so as to fill the patterning layer (photocurable composition for imprints) into the mold. After 10 seconds from the contact between the mold and the photocurable composition for imprints on the entire surface of the pattern region, exposure was carried out using a high pressure mercury lamp from the mold side at an irradiation dose of 300 mJ/cm², and thereafter the mold was peeled, whereby the pattern was transferred to the patterning layer.

The pattern, thus, transferred to the patterning layer was observed under an optical microscope (L200 D manufactured by Nikon Corporation), the number of bright points was determined in a dark field, and the number of defects per 1 cm² was calculated.

A: 300 or less

B: more than 300 and 500 or less

C: more than 500 and 700 or less

D: more than 700 and 1000 or less

E: more than 1000

The results are shown in the table below.

TABLE 8

| | Underlayer film | | | | |
|---|---|---|---|---|---|
| | | Coating | | Pattern | Pattern |
| | Ra | particles | Adhesiveness | defect 1 | defect 2 |
| Example 1-1 | 0.35 | A | B | A | A |
| Example 1-2 | 0.34 | A | B | A | A |
| Example 1-3 | 0.32 | A | A | A | A |
| Example 1-4 | 0.35 | A | B | A | B |
| Example 1-5 | 0.38 | A | S | A | B |
| Example 1-6 | 0.4 | A | S | A | B |
| Example 1-7 | 0.35 | A | B | A | A |
| Example 1-8 | 0.35 | A | B | A | A |
| Example 1-9 | 0.33 | A | S | A | A |
| Example 1-10 | 0.32 | A | S | A | A |
| Example 1-11 | 0.31 | A | S | B | C |
| Example 1-12 | 0.31 | A | S | A | A |
| Example 1-13 | 0.3 | A | S | A | A |
| Example 1-14 | 0.31 | A | S | A | A |
| Example 1-15 | 0.33 | A | S | A | A |
| Example 1-16 | 0.35 | A | A | A | B |
| Example 1-17 | 0.35 | A | A | B | C |
| Example 1-18 | 0.36 | A | A | A | A |
| Example 1-19 | 0.37 | A | A | A | A |
| Example 1-20 | 0.42 | A | A | A | A |
| Example 1-21 | 0.34 | A | A | A | A |
| Example 1-22 | 0.34 | A | A | A | A |
| Example 1-23 | 0.4 | A | A | A | A |
| Example 1-24 | 0.39 | A | B | A | B |
| Example 1-25 | 0.42 | A | B | A | B |
| Example 1-26 | 0.38 | B | A | B | C |
| Example 1-27 | 0.43 | B | A | B | C |
| Example 1-28 | 0.37 | B | A | B | C |
| Example 1-29 | 0.43 | B | A | B | C |
| Example 1-30 | 0.38 | A | A | A | A |
| Example 1-31 | 0.36 | A | A | A | A |
| Example 1-32 | 0.37 | A | A | A | A |
| Example 1-33 | 0.31 | A | B | A | A |
| Example 1-34 | 0.33 | A | B | A | A |
| Comparative | 0.6 | C | A | E | E |
| Example 1-1 | | | | | |
| Comparative | 0.7 | C | A | E | E |
| Example 1-2 | | | | | |
| Comparative | 0.9 | D | A | E | E |
| Example 1-3 | | | | | |
| Comparative | 0.8 | D | A | E | E |
| Example 1-4 | | | | | |
| Comparative | 0.33 | A | C | E | E |
| Example 1-5 | | | | | |
| Comparative | 0.33 | A | C | E | E |
| Example 1-6 | | | | | |
| Comparative | 0.4 | C | C | E | E |
| Example 1-7 | | | | | |
| Comparative | 0.5 | C | C | E | E |
| Example 1-8 | | | | | |

TABLE 9

| | Underlayer film | | | | |
|---|---|---|---|---|---|
| | | Coating | | Pattern | Pattern |
| | Ra | particles | Adhesiveness | defect 1 | defect 2 |
| Example 2-1 | 0.29 | A | A | A | A |
| Example 2-2 | 0.28 | A | A | A | A |
| Example 2-3 | 0.26 | A | S | A | A |
| Example 2-4 | 0.25 | A | S | A | A |
| Example 2-5 | 0.31 | A | B | A | B |
| Example 2-6 | 0.29 | A | B | A | B |
| Example 2-7 | 0.42 | A | S | A | B |
| Example 2-8 | 0.39 | A | S | B | C |
| Example 2-9 | 0.4 | A | S | A | A |
| Example 2-10 | 0.43 | A | S | A | A |
| Comparative | 0.78 | C | A | E | E |
| Example 2-1 | | | | | |
| Comparative | 0.54 | C | C | E | E |
| Example 2-2 | | | | | |

As is apparent from the above results, the resin composition for underlayer film formation of the Examples had good surface state and good adhesiveness. Furthermore, the surface roughness Ra was small and the number of coating particles was very small. Moreover, a pattern with fewer defects could be formed.

In contrast, the resin composition for underlayer film formation of the Comparative Examples was inferior in surface state of the underlayer film. Furthermore, there were many pattern defects.

<Preparation of Photocurable Composition V2 for Imprints>

A polymerizable compound, a photopolymerization initiator, and additives shown in the following table were mixed. Further, 4-hydroxy-2,2,6,6-tetramethylpiperidine-1-oxyl free radicals (manufactured by Tokyo Chemical Industry Co., Ltd.) as a polymerization inhibitor were added to 200 ppm (0.02 mass %) relative to the monomer. This was filtered through a PTFE filter having a pore size of 0.1 μm to prepare a photocurable composition V2 for imprints. In the table, individual components are given in terms of mass ratio.

TABLE 10

| | | Mass |
|---|---|---|
| | Available from | ratio |
| M-1 | VISCOAT #192 (manufactured by Osaka Organic | 25 |
| | Chemical Industry, Ltd.) | |
| M-4 | VISCOAT #230 (manufactured by Osaka Organic | 50 |
| | Chemical Industry, Ltd.) | |
| M-5 | IBXA (manufactured by Osaka Organic Chemical | 25 |
| | Industry, Ltd.) | |
| W-1 | Capstone FS-3100 (manufactured by E.I. du Pont de | 1 |
| | Nemours and Company Co., Ltd.) | |
| Photopoly- | Irgacure 819 (manufactured by BASF Corporation) | 2 |
| merization | | |
| initiator | | |

When evaluation of pattern defect 1 was carried out in the same manner as above by using the photocurable composition V2 for imprints in place of the photocurable composition V1 for imprints as a photocurable composition for imprints, in any case of the photocurable compositions for imprints, there were fewer pattern defects in the case of using the resin composition for underlayer film formation of the Examples than in the case of using the resin composition for underlayer film formation of the Comparative Examples.

### EXPLANATION OF REFERENCES

1: base material, 2: underlayer film, 3: imprint layer, 4: mold

What is claimed is:

1. A resin composition for underlayer film formation, comprising:
a resin;
a nucleophilic catalyst; and
a solvent,
wherein the content of the nucleophilic catalyst is 0.01 to 3 mass % with respect to the solid content of the resin composition for underlayer film formation.

2. The resin composition for underlayer film formation according to claim 1, wherein the nucleophilic catalyst is at least one selected from an ammonium salt, a phosphine-based compound, a phosphonium salt, and a heterocyclic compound.

3. The resin composition for underlayer film formation according to claim 1, wherein the resin includes a resin having a radical reactive group.

4. The resin composition for underlayer film formation according to claim 1, wherein the resin includes a resin having a radical reactive group and at least one group selected from a group represented by General Formula (B), an oxiranyl group, an oxetanyl group, a nonionic hydrophilic group, and a group having an interaction with a base material in the side chain thereof, 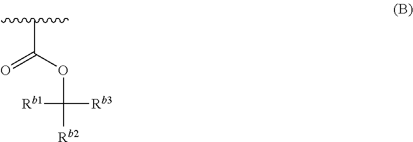
in General Formula (B), the wavy line represents a position connecting to the main chain or side chain of the resin, and
R^{b1}, R^{b2}, and R^{b3} each independently represent a group selected from an unsubstituted linear alkyl group having 1 to 20 carbon atoms, an unsubstituted branched alkyl group having 3 to 20 carbon atoms, and an unsubstituted cycloalkyl group having 3 to 20 carbon atoms, and
two of R^{b1}, R^{b2}, and R^{b3} may be bonded to each other to form a ring.

5. The resin composition for underlayer film formation according to claim 1, wherein the resin has at least one repeating unit selected from General Formulae (X1) to (X4), 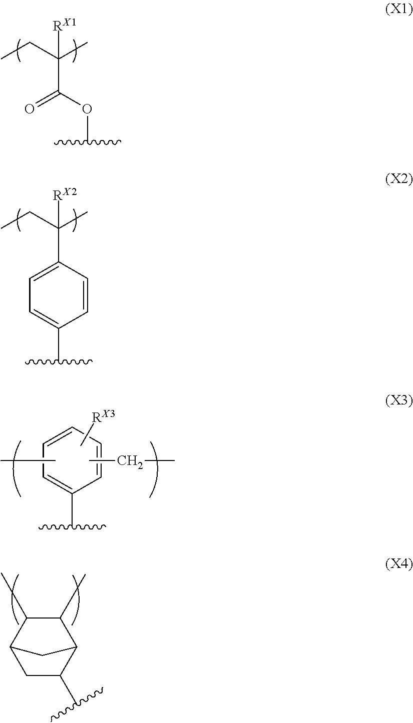
in General Formulae (X1) to (X4), R^{X1}, R^{X2}, and R^{X3} each independently represent a hydrogen atom or a methyl group, and the wavy line represents a position connecting to an atom or atomic group constituting a repeating unit of the resin.

6. The resin composition for underlayer film formation according to claim 1, wherein the content of water is 0.01 to 3 mass % with respect to the resin composition for underlayer film formation.

7. The resin composition for underlayer film formation according to claim 1, wherein the content of the solvent is 95 to 99.9 mass % with respect to the resin composition for underlayer film formation.

8. The resin composition for underlayer film formation according to claim 1, which is used for the formation of an underlayer film for photoimprints.

9. An imprint forming kit comprising:
the resin composition for underlayer film formation according to claim 1; and
a photocurable composition.

10. A laminate comprising an underlayer film obtained by curing the resin composition for underlayer film formation according to claim 1 on a surface of a base material.

11. A pattern forming method, comprising:
applying the resin composition for underlayer film formation according to claim 1 onto the surface of a base material in the form of layer;
heating the applied resin composition for underlayer film formation to form an underlayer film;
applying a photocurable composition in the form of layer onto the surface of the underlayer film, or a mold having a pattern;
sandwiching the photocurable composition between the mold and the base material;
curing the photocurable composition by photoirradiation in a state of the photocurable composition being sandwiched between the mold and the base material; and
peeling the mold.

12. A method for producing a device comprising the pattern forming method according to claim 11.
